(19) United States
(12) Patent Application Publication
(10) Pub. No.: US 2026/0247845 A1
(43) Pub. Date: Aug. 20, 2026

(54) LIGHT-EMITTING APPARATUS, DISPLAY APPARATUS, PHOTOELECTRIC CONVERSION APPARATUS, ELECTRONIC DEVICE, EYEGLASSES, AND MOVABLE BODY

(71) Applicant: CANON KABUSHIKI KAISHA, Tokyo (JP)

(72) Inventors: HIROAKI SANO, Tokyo (JP); NORIFUMI KAJIMOTO, Kanagawa (JP); SHOMA HINATA, Kanagawa (JP)

(21) Appl. No.: 19/540,406

(22) Filed: Feb. 13, 2026

(30) Foreign Application Priority Data
Feb. 19, 2025 (JP) 2025-024828
Nov. 6, 2025 (JP) 2025-187462

(51) Int. Cl. H10K 59/80; H10K 59/38

(52) U.S. Cl. CPC H10K 59/879; H10K 59/38

(57) ABSTRACT

A light-emitting apparatus including a first light-emitting element disposed in a center portion of a display region, a first lens corresponding to the first light-emitting element, a second light-emitting element disposed in a peripheral portion of the display region, and a second lens corresponding to the second light-emitting element, wherein an amount of shift between the second light-emitting element and the second lens is greater than an amount of shift between the first light-emitting element and the first lens, wherein a focal length of the second lens is longer than a focal length of the first lens, and wherein a distance from a lower surface to a vertex of the second lens in a direction perpendicular to a main surface is smaller than a distance from a lower surface to a vertex of the first lens in the perpendicular direction.

### BACKGROUND

### Field of the Technology

The present disclosure relates to a light-emitting apparatus including an optical member, such as a microlens or the like, a display apparatus, a photoelectric conversion apparatus, an electronic device, eyeglasses and a movable body.

### Description of the Related Art

An organic light-emitting element is an element including a first electrode, a second electrode, and an organic compound layer placed between the first and second electrodes and is a light-emitting device that emits light by injecting carriers from the first and second electrodes into the light-emitting device. Since the organic light-emitting element is a device that is light in weight and can be made flexible, in recent years, a display apparatus or the like including the organic light-emitting element draws attention. To achieve a high definition of the display apparatus, a method for using an organic light-emitting element that emits white light and a color filter (hereinafter referred to as a “white +CF method”) is known. Since the white+CF method forms a film of an organic layer on the entire surface of a substrate, it is relatively easier to achieve a high definition regarding the pixel size, the pitch between pixels, and the like than a method for forming a film of an organic layer on a color-by-color basis using a metal mask.

Japanese Patent Laid-Open No. 2020-184478 describes a technique for using a display apparatus including an organic light-emitting element with an optical system.

Japanese Patent Laid-Open No. 2020-184478 describes a display apparatus in which viewing angle characteristics are improved by placing the center of a light-emitting surface of a light exit portion and the center of a microlens in a relatively shifted manner.

### SUMMARY

As an aspect of the present disclosure, it is possible to prevent a decrease in luminance in a light-emitting apparatus.

According to an aspect of the present disclosure, a light-emitting apparatus includes a first light-emitting element disposed on a surface of a substrate in a first region, a first lens disposed on the first light-emitting element and corresponding one-on-one to the first light-emitting element, a second light-emitting element disposed on the surface of the substrate in a second region, and a second lens disposed on the second light-emitting element and corresponding one-on-one to the second light-emitting element, wherein the first and second regions are included in a display region, wherein, in a first direction, a shortest distance from an end of the display region to the first region is greater than a shortest distance from the end of the display region to the second region, wherein, in a planar view of the surface of the substrate, a distance in the first direction between a midpoint in the first direction of a light-emitting region of the second light-emitting element and a vertex of the second lens is longer than a distance in the first direction between a midpoint in the first direction of a light-emitting region of the first light-emitting element and a vertex of the first lens, wherein a focal length of the second lens is longer than a focal length of the first lens, and wherein a distance from a lower surface to the vertex of the second lens in a direction perpendicular to the surface of the substrate is smaller than a distance from a lower surface to the vertex of the first lens in the perpendicular direction.

According to another aspect of the present disclosure, a light-emitting apparatus includes a first light-emitting element disposed on a surface of a substrate in a first region, a first lens disposed on the first light-emitting element and corresponding one-on-one to the first light-emitting element, and a second light-emitting element disposed on the surface of the substrate in a second region, wherein the first and second regions are included in a display region, wherein in a planar view of the surface of the substrate, the first region is surrounded by the second region, and wherein the light-emitting apparatus does not include a lens corresponding to the second light-emitting element.

Features of the present disclosure will become apparent from the following description of embodiments with reference to the attached drawings. The following description of embodiments is described by way of example.

### BRIEF DESCRIPTION OF THE DRAWINGS

FIG. 1A is a plan view illustrating a light-emitting apparatus according to an embodiment. FIG. 1B is a cross-sectional view of the light-emitting apparatus in FIG. 1A.

FIGS. 2A and 2B are schematic views illustrating focal lengths.

FIG. 3A is a cross-sectional view illustrating the light-emitting apparatus according to the embodiment. FIG. 3B is a cross-sectional view illustrating the light-emitting apparatus according to the embodiment.

FIG. 4A is a cross-sectional view illustrating the light-emitting apparatus according to the embodiment. FIG. 4B is a cross-sectional view illustrating the light-emitting apparatus according to the embodiment.

FIG. 5A is a cross-sectional view illustrating the light-emitting apparatus according to the embodiment. FIG. 5B is a cross-sectional view illustrating the light-emitting apparatus according to the embodiment.

FIG. 6 is a cross-sectional view illustrating the light-emitting apparatus according to the embodiment.

FIG. 7A is a plan view illustrating a light-emitting apparatus according to an embodiment. FIG. 7B is a cross-sectional view of the light-emitting apparatus in FIG. 7A.

FIG. 8 is a cross-sectional view illustrating the light-emitting apparatus according to the embodiment.

FIG. 9 is a schematic cross-sectional view of a light-emitting apparatus according to a comparative example.

FIG. 10 is a schematic cross-sectional view of a light-emitting apparatus according to a comparative example.

FIG. 11 is a cross-sectional view illustrating the light-emitting apparatus according to the embodiment.

FIG. 12 is a cross-sectional view illustrating the light-emitting apparatus according to the embodiment.

FIG. 13 is a schematic cross-sectional view of a light-emitting apparatus according to a comparative example.

FIG. 14 is a schematic cross-sectional view of a light-emitting apparatus according to a comparative example.

FIG. 15 is a cross-sectional view illustrating the light-emitting apparatus according to the embodiment.

FIG. 16 is a cross-sectional view illustrating the light-emitting apparatus according to the embodiment.

FIG. 17 is a cross-sectional view illustrating the light-emitting apparatus according to the embodiment.

FIG. 18A is a schematic view illustrating positional relationships between a lens, the light-emitting apparatus, and an observer. FIG. 18B is a schematic view illustrating positional relationships between the lens, the light-emitting apparatus, and the observer.

FIGS. 19A and 19B are diagrams for describing a correspondence between a microlens and a light-emitting element.

FIG. 20A is a graph illustrating luminance with respect to an exit angle in a pixel in which the microlens is disposed. FIG. 20B is a graph illustrating a chromaticity difference with respect to the exit angle in the pixel in which the microlens is disposed.

FIG. 20C is a graph illustrating an sRGB cover rate with respect to the exit angle in the pixel in which the microlens is disposed.

FIG. 21A is a graph illustrating luminance with respect to an exit angle in a pixel in which the microlens is not disposed. FIG. 21B is a graph illustrating a chromaticity difference with respect to the exit angle in the pixel in which the microlens is not disposed.

FIG. 21C is a graph illustrating an sRGB cover rate with respect to the exit angle in the pixel in which the microlens is not disposed.

FIG. 22 is a schematic cross-sectional view illustrating an example of a pixel of a display apparatus according to an embodiment.

FIG. 23 is a schematic view illustrating an example of a display apparatus according to the embodiment.

FIG. 24A is a schematic view illustrating an example of an imaging apparatus according to the embodiment. FIG. 24B is a schematic view illustrating an example of an electronic device according to the embodiment.

FIG. 25A is a schematic view illustrating an example of a display apparatus according to the embodiment. FIG. 25B is a schematic view illustrating an example of a foldable display apparatus.

FIG. 26A is a schematic view illustrating an example of a wearable device according to the embodiment. FIG. 26B is a schematic view illustrating an example of a wearable device according to the embodiment and a form in which the wearable device includes an imaging apparatus.

FIG. 27A is a schematic view of an image forming apparatus according to the embodiment. FIGS. 27B and 27C are schematic views illustrating forms in which a plurality of light-emitting units of an exposure light source is placed on a long substrate.

FIG. 28 is a schematic view illustrating an example of an automobile including a lamp or a display unit for a vehicle according to the embodiment.

FIGS. 29A to 29C are schematic views illustrating examples of area gradation patterns placed in an area gradation mask used to form the microlens according to the embodiment.

### DESCRIPTION OF THE EMBODIMENTS

Hereinafter, embodiments will be described with reference to the drawings. It should be noted that the following embodiments do not limit the present disclosure. Although a plurality of configurations is described in the embodiments, not all of these configurations are necessarily essential to the invention, and the configurations may be combined arbitrarily. In the drawings, identical or similar components are denoted by the same reference numerals, and redundant descriptions may be omitted.

### First Embodiment

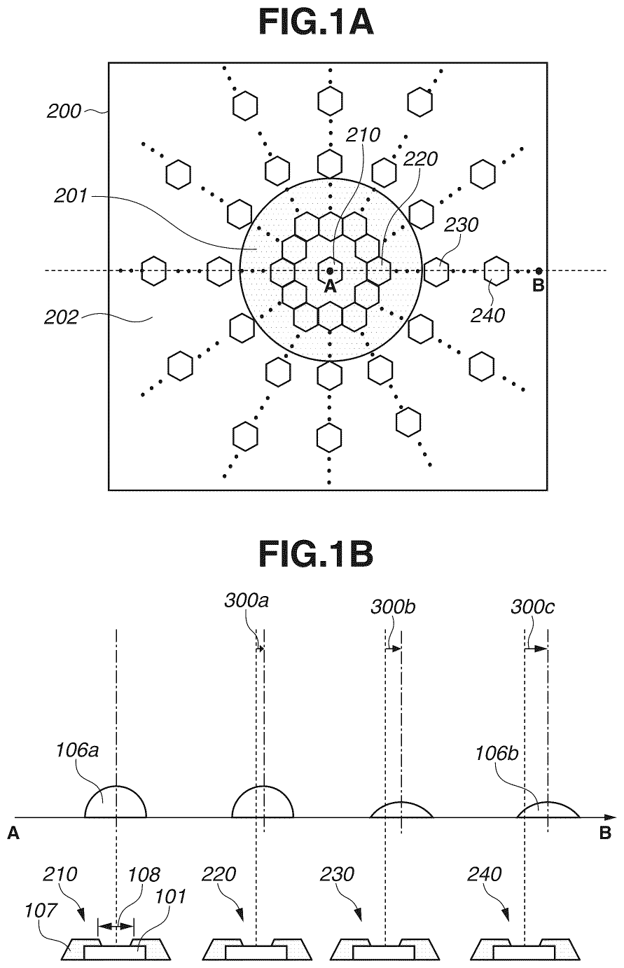

FIGS. 1A and 1B are diagrams illustrating an example of a light-emitting apparatus according to a first embodiment.

FIG. 1A is a diagram illustrating a planar view of the light-emitting apparatus in a direction perpendicular to a main surface of a substrate. In the present embodiment, the light-emitting apparatus includes a display region, and the display region includes a first region and a second region. In the planar view of the main surface of the substrate, the shortest distance from an end of the display region in a first direction to the first region is greater than the shortest distance from the end of the display region in the first direction to the second region. The main surface of the substrate refers to a surface on which light-emitting elements are disposed among the surfaces of the substrate.

The light-emitting apparatus illustrated in FIG. 1A includes a first light-emitting element disposed on the main surface and a first lens disposed on the first light-emitting element and corresponding one-on-one to the first light-emitting element in the first region. The light-emitting apparatus also includes a second light-emitting element disposed on the main surface and a second lens disposed on the second light-emitting element and corresponding one-on-one to the second light-emitting element in the second region. The focal length of the second lens is longer than the focal length of the first lens.

A lens corresponding one-on-one to a certain light-emitting element refers to a lens that overlaps a light-emitting region such that the area of the overlap is less than or equal to the area of the light-emitting region in the planar view of the main surface.

If a lens overlaps a plurality of light-emitting regions in the planar view, this means that the total area of the overlap of the light-emitting regions with the lens is less than or equal to the area of the largest light-emitting region among the plurality of light-emitting regions overlapping the lens. That is, in the display region of the light-emitting apparatus according to the present embodiment, a single lens does not mainly collect light from a plurality of light-emitting regions, and a single lens mainly functions for light from a single light-emitting region.

With reference to FIGS. 1A and 1B, a more specific configuration is described. A display region 200 includes a plurality of light-emitting elements. In a direction from a center portion A to an outer peripheral portion B of the display region 200 (a first direction), a light-emitting element 210, a light-emitting element 220, a light-emitting element 230, and a light-emitting element 240 are disposed in this order. Light-emitting elements disposed between these light-emitting elements are omitted for convenience. An example is illustrated where the display region 200 includes a first region 201 including the light-emitting elements 210 and 220, and a second region 202 including the light-emitting elements 230 and 240.

FIG. 1B is an example of a part of a cross-sectional view along a straight line A-B in FIG. 1A. In this cross section, some light-emitting elements are omitted. In FIG. 1B, the light-emitting apparatus includes a lower electrode 101, an insulating layer 107 that covers both ends of the lower electrode 101, and a microlens 106 (106a, 106b). The insulating layer 107 is also termed a “pixel separation film” or a “bank”, and an opening portion is provided such that a part of the lower electrode 101 is exposed. The opening portion is a light-emitting region 108. On the lower electrode 101, functional layers including a light-emitting layer, an upper electrode, a protection layer, a planarization film, and the like are disposed, but are omitted for convenience in FIG. 1B.

The first region 201 includes a microlens 106a (a first lens) having a short focal length, and the second region 202 includes a microlens 106b (a second lens) having a long focal length. A “focal length” refers to the distance between a point (a focal point) where light passing through the microlens 106 is collected and the bottom surface of the microlens 106 when a plurality of rays parallel to each other (parallel beams of light) in the direction perpendicular to the main surface of the substrate is incident on the microlens 106. At this time, the focal length is the distance between the bottom surface of the microlens 106 and the focal point in a direction perpendicular to the bottom surface of the microlens 106. In the specification, the microlens 106 refers to a microlens having a finite focal length, and does not include a microlens having an infinite focal length.

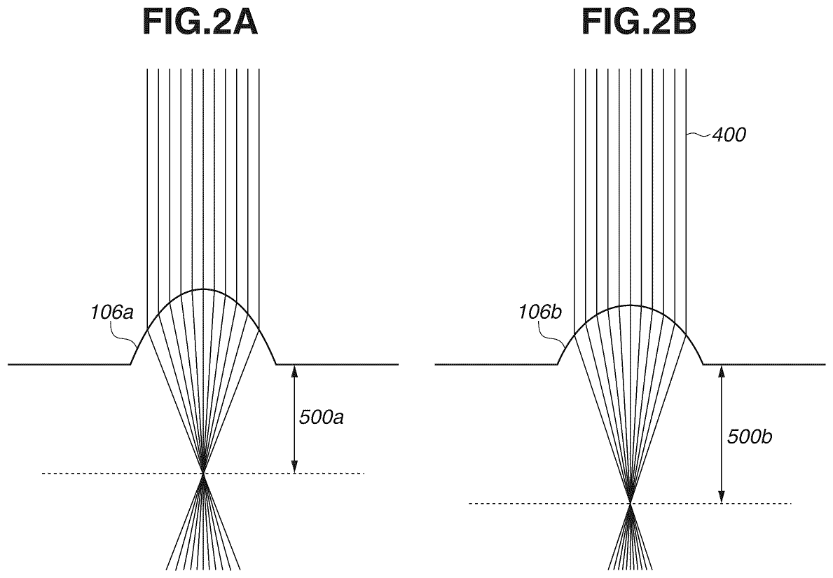

In FIG. 2A, the focal length when parallel beams of light 400 are incident on the microlens 106a is a distance 500a. In FIG. 2B, the focal length when the parallel beams of light 400 are incident on the microlens 106b is a distance 500b. At this time, the distance 500b is longer than the distance 500a, and the microlens 106b can be said to be a microlens having a longer focal length than that of the microlens 106a.

Further, in FIG. 1B, the positional relationship between the microlens 106 and the light-emitting region 108 changes in the direction from A to B. A specific description is given based on the positional relationship between the light-emitting region 108 of the light-emitting element 210 and the microlens 106a disposed immediately above the light-emitting region 108. The microlens 106a is shifted by a shift amount 300a in the direction from the center portion A to the peripheral portion B of the display region 200 (the right direction in FIG. 1B) relative to the light-emitting region 108 of the light-emitting element 220.

Similarly, the microlens 106b is shifted by a shift amount 300b in the direction from the center portion A to the end of the display region 200 relative to the light-emitting region 108 of the light-emitting element 230. Further, the microlens 106b is shifted by a shift amount 300c in the direction from the center portion A to the end of the display region 200 relative to the light-emitting region 108 of the light-emitting element 240.

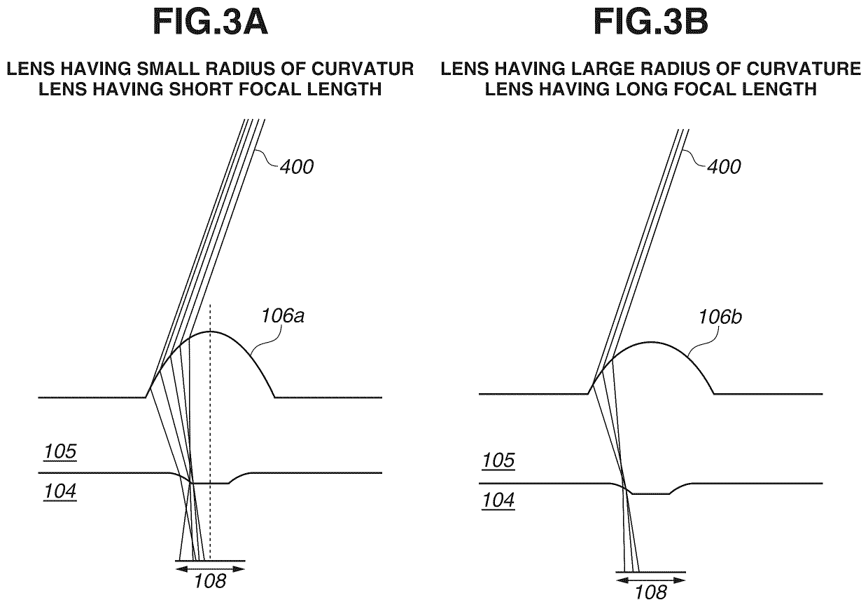

FIGS. 3A and 3B illustrate the results of ray simulations. FIG. 3A illustrates a light-emitting region 108, a protection layer 104, a planarization layer 105, and a microlens 106a corresponding one-on-one to the light-emitting region 108, and the path of light passing through the microlens 106a. The microlens 106a is disposed immediately above the light-emitting region 108 and has a short focal length. FIG. 3B illustrates a light-emitting region 108, a protection layer 104, a planarization layer 105, and a microlens 106b corresponding one-on-one to the light-emitting region 108, and the path of light passing through the microlens 106b. The microlens 106b is disposed immediately above the light-emitting region 108 and has a long focal length, which is longer than that of the microlens 106a.

It is understood from FIGS. 3A and 3B that the number of rays 400 emitted to the wide-angle side is greater in the microlens 106a. That is, when the microlens 106 is located immediately above the light-emitting region 108, the microlens 106a having a short focal length can increase the intensity on the wide-angle side more.

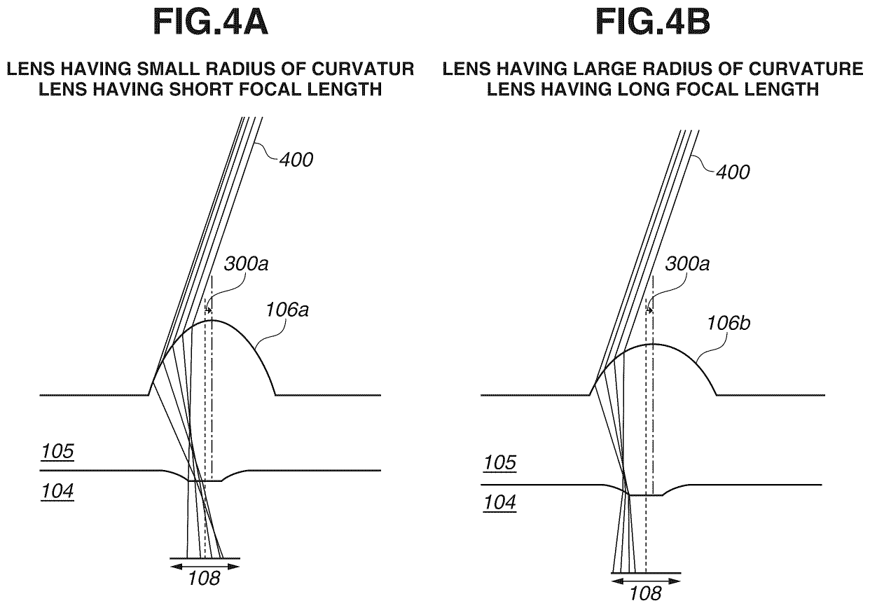

FIGS. 4A and 4B illustrate the results of ray simulations. FIG. 4A illustrates a light-emitting region 108, a protection layer 104, a planarization layer 105, and a microlens 106a corresponding one-on-one to the light-emitting region 108, and the path of light passing through the microlens 106a.

In FIG. 4A, the microlens 106a is shifted by a shift amount 300a in the right direction in FIG. 4A relative to the light-emitting region 108.

FIG. 4B illustrates a light-emitting region 108, a protection layer 104, a planarization layer 105, and a microlens 106b corresponding one-on-one to the light-emitting region 108, and the path of light passing through the microlens 106b. In FIG. 4B, the microlens 106b is shifted by the shift amount 300a in the right direction in FIG. 4B relative to the light-emitting region 108.

It is understood from FIGS. 4A and 4B that the number of rays 400 emitted to the wide-angle side is greater in the microlens 106a. That is, when the microlens 106 is located slightly shifted from the light-emitting region 108, the microlens 106a having a short focal length can increase the intensity on the wide-angle side more.

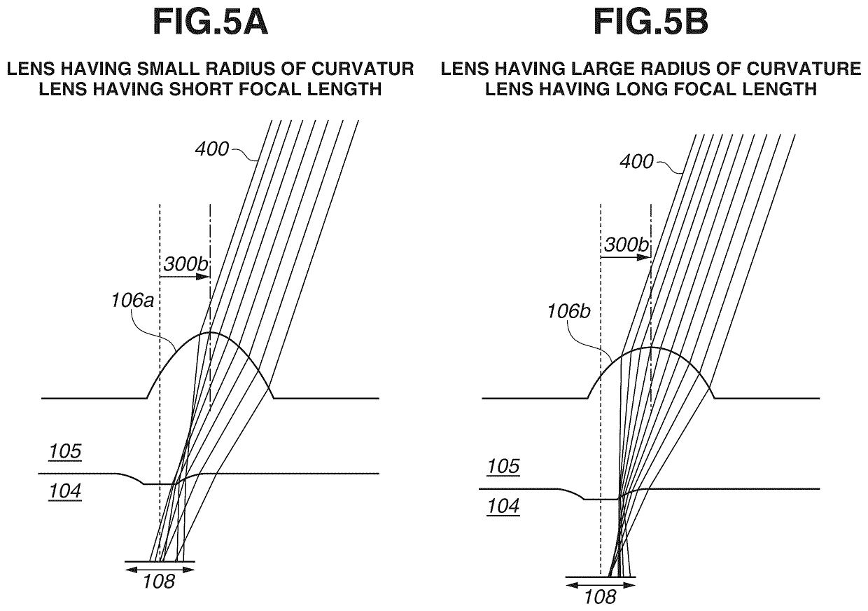

Further, FIGS. 5A and 5B illustrate the results of ray simulations. FIG. 5A illustrates a light-emitting region 108, a protection layer 104, a planarization layer 105, and a microlens 106a corresponding one-on-one to the light-emitting region 108, and the path of light passing through the microlens 106a. In FIG. 5A, the microlens 106a is shifted by a shift amount 300b in the right direction in FIG. 5A relative to the light-emitting region 108.

FIG. 5B illustrates a light-emitting region 108, a protection layer 104, a planarization layer 105, and a microlens 106b corresponding one-on-one to the light-emitting region 108, and the path of light passing through the microlens 106b. In FIG. 5B, the microlens 106b is shifted by the shift amount 300b in the right direction in FIG. 5B relative to the light-emitting region 108.

It is understood from FIGS. 5A and 5B that the number of rays 400 emitted to the wide-angle side is greater in the microlens 106b. That is, if the amount of shift of the microlens 106 from the light-emitting region 108 is great, the microlens 106b having a long focal length can increase the intensity on the wide-angle side more.

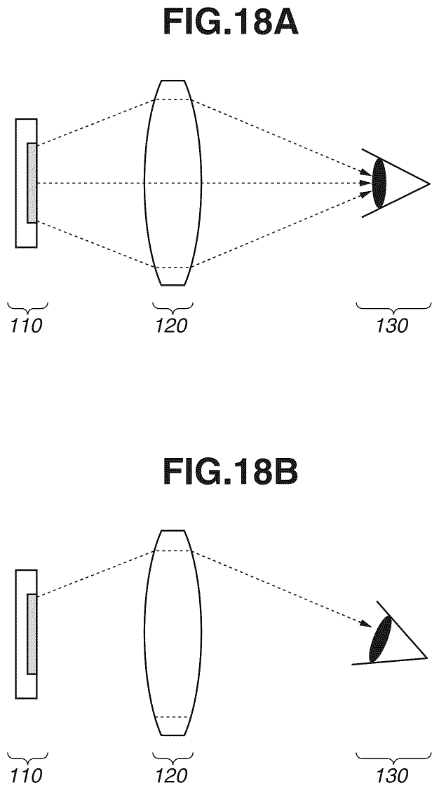

FIG. 18A is a diagram illustrating the outline of a ray from a light-emitting mechanism 110 including a light-emitting element and a microlens to an eyeball of a user in a case where the light-emitting apparatus includes an eyepiece optical system.

The eyepiece optical system can guide light from the microlens to an exit pupil. As illustrated in FIG. 18A, in a case where the light-emitting mechanism 110 is used with an optical lens 120 included in the eyepiece optical system, in a center portion of a display region, an image is formed on an eyeball 130 using a ray traveling in the front direction of a display surface. In contrast, in an outer peripheral portion of the display region, an image is formed on the eyeball 130 using light traveling in an oblique direction of the display surface.

That is, a light-emitting element located in an outer peripheral region uses light in which the exit angle of the light from the light-emitting element is a wide angle. Thus, for example, in a case where the light-emitting apparatus includes the eyepiece optical system, the light use efficiency of light from the light-emitting element is improved, whereby it is possible to improve the luminance of the light-emitting apparatus.

The viewing angle characteristics of light from the light-emitting element are improved, whereby it is possible to improve the viewing angle characteristics of the light-emitting apparatus.

In the light-emitting apparatus in FIG. 1B, the microlens 106a disposed in the first region 201 is disposed immediately above the light-emitting region 108 of the light-emitting element 210, and the microlens 106a is disposed in a shifted manner by the shift amount 300a in the right direction in FIG. 1B relative to the light-emitting element 220. The shift amount 300a is smaller than the shift amount 300b. Thus, the microlens 106a having a short focal length is placed one-on-one for each of the light-emitting elements 210 and 220, whereby it is possible to increase the intensity on the wide-angle side compared to a case where the microlens 106b having a long focal length is placed.

On the other hand, the microlens 106b disposed in the second region 202 is disposed in a shifted manner by the shift amount 300b in the right direction in FIG. 1B relative to the light-emitting element 230. The microlens 106b is also disposed in a shifted manner by the shift amount 300c in the right direction in FIG. 1B relative to the light-emitting element 240. Even if the center of the light-emitting region 108 and the center of the microlens 106 are placed shifted relative to each other, the light intensity may decrease at a wider viewing angle, and the display quality may decrease.

The microlens 106b having a long focal length is placed for each of the light-emitting elements 230 and 240, whereby it is possible to increase the intensity on the wide-angle side compared to a case where the microlens 106a having a short focal length is placed. Thus, also in a case where the microlens 106b is disposed, it is possible to prevent a decrease in luminance at a wide viewing angle.

That is, the light-emitting apparatus has the configuration according to the present embodiment, whereby it is possible to increase the intensity on the wide-angle side in the entirety of the display region 200.

The microlens 106a may have a small radius of curvature, and the microlens 106b may have a large radius of curvature. For example, the distance from the lower surface to the vertex of the microlens 106b may be smaller than the distance from the lower surface to the vertex of the microlens 106a. At this time, for example, if the areas of the lower surfaces of the microlenses 106a and 106b are the same as or close to each other, the focal length of the microlens 106b is longer than the focal length of the microlens 106a. Thus, even if the area of the microlens 106 is not changed with respect to each light-emitting element, it is possible to dispose microlenses 106 having different focal lengths.

If the area of the lower surface of the microlens 106 is differentiated with respect to each sub-pixel, the areas of the sub-pixels are also different from each other, or a gap occurs between microlenses 106. If the area of each sub-pixel is different, it is necessary to change the dimensions of elements with respect to each pixel, and it is difficult to manufacture the microlens 106. If a gap occurs between microlenses 106, light that does not pass through the microlenses 106 occurs in light from the light-emitting elements. Thus, the outcoupling efficiency decreases.

On the other hand, the distance from the lower surface to the vertex of the microlens 106 is changed, whereby it is possible to adjust the focal length of the microlens 106 without differentiating the area of the lower surface of the microlens 106 with respect to each sub-pixel. Thus, it is possible to differentiate the focal length of the microlens 106 with respect to each sub-pixel without the area of each sub-pixel being different or a gap occurring between microlenses 106. Thus, it is possible to increase the intensity of light on the wide-angle side in the entirety of the display region 200.

The lower surface of the microlens 106 refers to a surface formed by a line composed of a set of points at the greatest angle to the main surface of the substrate on the upper surface of the microlens 106. The distance from the lower surface to the vertex of the microlens 106 refers to the length of a line segment extending perpendicularly from the vertex of the microlens 106 to the lower surface of the microlens 106.

Although in FIGS. 1A and 1B, the microlens 106 is placed shifted in the peripheral direction of the display region 200 (the direction from the center portion A to the peripheral portion B of the display region 200) relative to the light-emitting region 108, the light-emitting apparatus according to the present embodiment is not limited to this. In the light-emitting apparatus according to the present embodiment, the microlens 106 may be placed shifted in the central direction of the display region 200 (a direction from the peripheral portion B to the center portion A of the display region 200) relative to the light-emitting region 108. In other words, the microlens 106 may be placed shifted in the left direction in FIG. 1B relative to the light-emitting region 108.

In a case where the light-emitting mechanism 110 is used with the optical lens 120 as illustrated in FIG. 18A, the direction of light of the light-emitting mechanism 110 differs depending on the optical lens 120 to be combined, and therefore, the direction of shifting the microlens 106 may be changed.

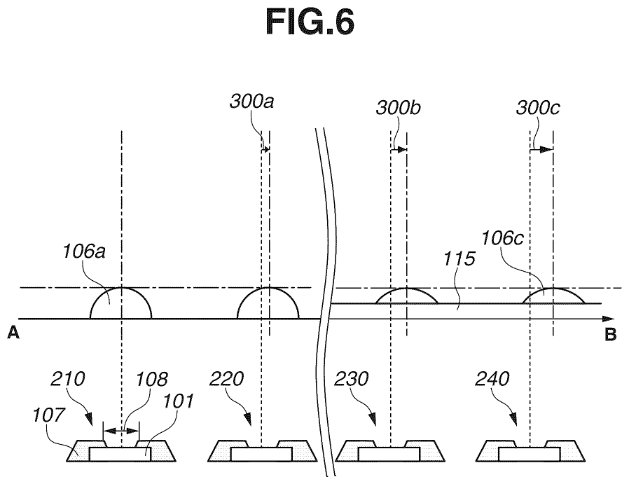

With reference to FIG. 6, an example of the form of the light-emitting apparatus according to the present embodiment is described. In a cross section perpendicular to the substrate, the distance from the main surface of the substrate to the lower surface of the microlens 106a in a second direction perpendicular to the main surface is smaller than the distance in the second direction from the main surface to the lower surface of a microlens 106c. The cross section perpendicular to the substrate refers to a cross section passing through the light-emitting element 210 or 220, the second light-emitting element 240, the microlens 106a, and the microlens 106c.

There is a case where the height of a microlens 106 (the distance between the lower surface and the vertex of the microlens 106 in a direction perpendicular to the lower surface) having a long focal length is smaller than that of a microlens 106 having a short focal length.

In this case, the distance from the main surface of the substrate to the lower surface of the microlens 106 having a short focal length is made smaller than the distance from the main surface of the substrate to the lower surface of the microlens 106 having a long focal length, whereby it is possible to reduce the difference between the distances between the main surface of the substrate and the vertices of the microlenses 106 in the second direction.

As illustrated in FIG. 6, the height of the vertex of the microlens 106c corresponding to each of the light-emitting elements 230 and 240 may be matched to that of the microlens 106a. For example, the height of an insulating layer disposed between the microlens 106 and the light-emitting element is changed, whereby it is possible to match the heights of the vertices of a plurality of microlenses 106. FIG. 6 illustrates an example where an insulating layer 115 is included on an insulating layer serving as a base of the microlens 106. The heights of the vertices of microlenses 106 are matched to each other, whereby it is possible to form the microlenses 106 at a time. Thus, it is possible to reduce the number of steps in the creation of the microlens 106.

In the planar view of the main surface of the substrate, the area of the second region 202 may cover 5% to 90% of the area of the display region 200. In a case where the light-emitting mechanism 110 is used with the optical lens 120 as illustrated in FIG. 18A, the microlens 106b may be placed such that a region at which the user cannot gaze by rotating the eyeball 130 is the second region 202. That is, the second region 202 may be disposed at a position at which the user cannot gaze through the eyepiece optical system. At this time, in the planar view, the second region 202 may cover 10% to 40% of the area of the display region 200.

In a case where the user attempts to view an end of the display region 200 through the optical lens 120 by rotating the eyeball 130 as illustrated in FIG. 18B, a region at which the user can gaze may be a region narrower than the display region 200 because the angle at which a person can rotate their eyeballs is limited. However, although the user cannot gaze at the second region 202 by rotating the eyeball 130, light from the second region 202 reaches the eyeball 130, and therefore, the user can view video in the region at which the user cannot gaze.

That is, it can also be said that the placement of the microlens 106b such that a region at which the user cannot gaze by rotating the eyeball 130 is the second region 202 is the placement of the microlens 106b in a region at which the user cannot gaze but from which light reaches the eyeball 130. Thus, the microlens 106b having a long focal length is disposed in the second region 202, whereby it is possible to prevent a decrease in the luminance of video in the region at which the user cannot gaze but from which light reaches the eyeball 130. Thus, in a case where display is performed using the light-emitting apparatus, it is possible to increase the display quality.

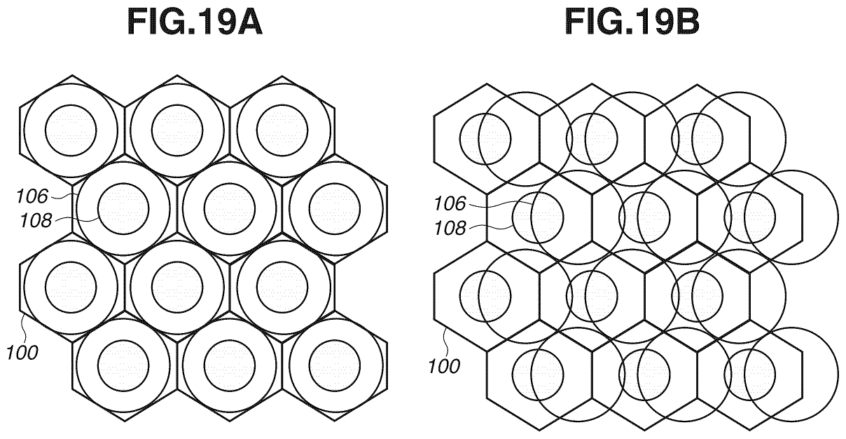

With reference to FIGS. 19A and 19B, a description is given of the state where a single microlens 106 corresponds one-on-one to a light-emitting element. FIG. 19A is a planar view of a part of the first region 201 in the direction perpendicular to the main surface of the substrate. That a single microlens 106 corresponds one-on-one to a single light-emitting element means that as illustrated in FIG. 19A, in the planar view of the main surface, the area of a region where the single microlens 106 and the light-emitting region 108 overlap each other is less than or equal to the area of the light-emitting region 108 of the light-emitting element.

The display region 200 may include a plurality of light-emitting elements including a first light-emitting element and a second light-emitting element, and a plurality of microlenses including a first microlens and a second microlens. In the plurality of microlenses, the amount of shift of each microlens relative to a light-emitting element corresponding to the microlens may differ in the first direction. For example, the following configuration may be employed. Among the plurality of light-emitting elements and the plurality of microlenses, in the planar view of the main surface of the substrate, as a position approaches from the center of the display region 200 toward the end of the display region 200, the vertex of each of the plurality of microlenses is shifted to the end side in the first direction relative to the midpoint of a light-emitting region corresponding to the microlens the vertex may be.

The display region 200 may include a plurality of two-dimensionally disposed pixels. Each of the plurality of pixels may include a plurality of sub-pixels. For example, sub-pixels included in a single pixel may emit light of different colors. In a case where a single microlens 106 corresponds one-on-one to a single light-emitting element, then as illustrated in FIG. 19A, in the planar view, the area of overlap between a single microlens 106 and a single sub-pixel 100 may be the same as the area of the single sub-pixel 100.

FIG. 19B is a planar view of a part of the second region 202 in the direction perpendicular to the main surface of the substrate. Also in the second region 202, similarly to the first region 201, a single microlens 106 corresponds one-on-one to a single light-emitting element. That is, in the planar view of the main surface, the area of a region where the single microlens 106 and the light-emitting region 108 overlap each other is less than or equal to the area of the light-emitting region 108 of the light-emitting element. Also in FIG. 19B, in the planar view in the direction perpendicular to the main surface of the substrate, the area of overlap between a single microlens 106 and a single sub-pixel 100 may be the same as the area of the single sub-pixel 100.

### Second Embodiment

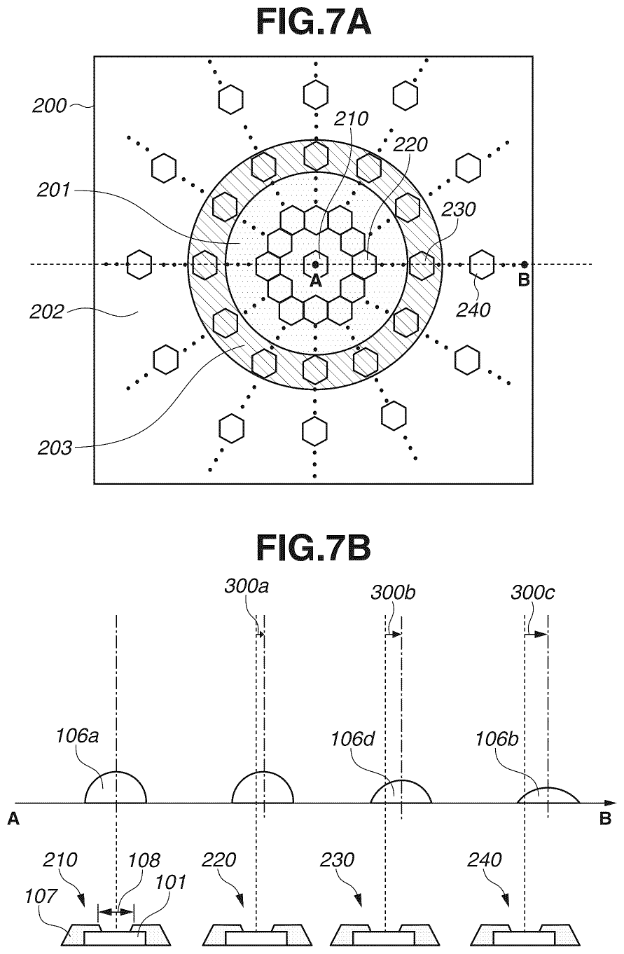

With reference to FIGS. 7A and 7B, an example of a light-emitting apparatus according to a second embodiment is described. Structures, functions, materials, effects, and the like similar to those according to the first embodiment are not described again. FIG. 7A is a diagram illustrating a planar view of the light-emitting apparatus in the direction perpendicular to the main surface of the substrate. In the light-emitting apparatus according to the present embodiment, a third region 203 is disposed in the display region 200 in addition to the light-emitting apparatus according to the first embodiment.

In the planar view of the main surface of the substrate, the display region 200 of the light-emitting apparatus according to the present embodiment includes a third region 203 disposed between the first region 201 and the second region 202 in the direction from the center portion A to the end (the peripheral portion B) of the display region 200 (the first direction). The light-emitting apparatus also includes a third light-emitting element disposed on the main surface of the substrate and a third lens disposed on the third light-emitting element and corresponding one-on-one to the third light-emitting element in the third region 203. The focal length of the third lens is longer than the focal length of the first lens, and the focal length of the third lens is shorter than the focal length of the second lens.

With reference to FIGS. 7A and 7B, the light-emitting apparatus according to the present embodiment is specifically described. An example is illustrated where the display region 200 is divided into a first region 201 including a light-emitting element 210 and a light-emitting element 220, a second region 202 including a light-emitting element 240, and a third region 203 including a light-emitting element 230. FIG. 7B is a part of a cross-sectional view along a straight line A-B in FIG. 7A.

The first region 201 includes a microlens 106a (a first lens) having a short focal length, and the second region 202 includes a microlens 106b (a second lens) having a long focal length. The third region 203 includes a microlens 106d (a third lens). The microlens 106d has a longer focal length than that of the microlens 106a and has a shorter focal length than that of the microlens 106b.

The positional relationship between the microlens 106d and the light-emitting region 108 changes in the direction from A to B. A specific description is given based on the positional relationship between the light-emitting region 108 of the light-emitting element 210 and the microlens 106a disposed immediately above the light-emitting region 108. The microlens 106d is shifted by a shift amount 300b in the direction from the center portion A to the peripheral portion B of the display region 200 (the right direction in FIG. 7B; the first direction) relative to the light-emitting region 108 of the light-emitting element 230.

Similarly to the light-emitting apparatus according to the first embodiment, in the light-emitting apparatus according to the present embodiment, a microlens 106 has a greater shift amount relative to a light-emitting region 108 corresponding one-on-one to the microlens 106 and has a longer focal length in the peripheral portion B than in the center portion A. Thus, it is possible to improve the light use efficiency of the entirety of the display region 200. Thus, it is possible to achieve a light-emitting apparatus having high luminance.

In the present embodiment, the third region 203 including the microlens 106d is provided between the first region 201 and the second region 202, whereby it is possible to moderate a change in the luminance between the first region 201 and the second region 202. Thus, when display is performed in the display region 200, it is possible to further improve the display quality.

### Third Embodiment

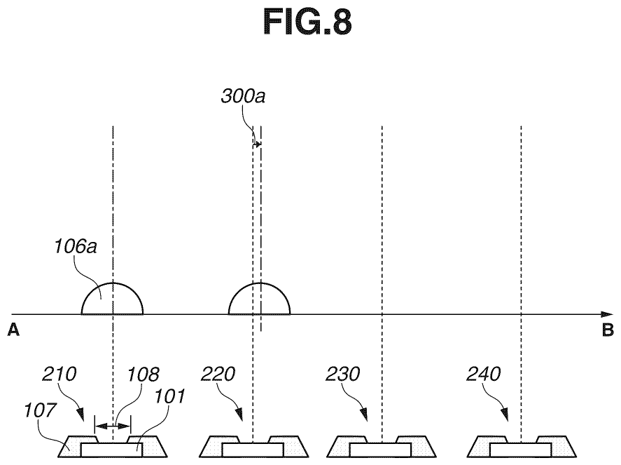

FIG. 8 is a diagram illustrating an example of a light-emitting apparatus according to a third embodiment. Structures, functions, materials, effects, and the like similar to those according to the first or second embodiment are not described again. FIG. 8 is a part of a cross-sectional view along a straight line A-B in FIG. 1A as an example of a part of the light-emitting apparatus. In this cross section, some light-emitting elements are omitted.

In the present embodiment, the light-emitting apparatus is different from the light-emitting apparatus according to the first embodiment in that a lens corresponding one-on-one to a light-emitting element is not disposed.

The display region 200 of the light-emitting apparatus includes a first region 201 and a second region 202 disposed around the first region 201. The light-emitting apparatus includes a first light-emitting element disposed on the main surface of the substrate and a first lens disposed on the first light-emitting element and corresponding one-on-one to the first light-emitting element in the first region 201. The light-emitting apparatus also includes a second light-emitting element disposed on the main surface in the second region 202.

As illustrated in FIG. 8, while the light-emitting apparatus according to the present embodiment includes a microlens 106a corresponding one-on-one to each of a light-emitting element 210 and a light-emitting element 220, the light-emitting apparatus according to the present embodiment does not include microlenses 106 corresponding to a light-emitting element 230 and a light-emitting element 240.

The positional relationship between the microlens 106 and the light-emitting region 108 changes in the direction from A to B. A specific description is given based on the positional relationship between the light-emitting region 108 of the light-emitting element 210 and the microlens 106a disposed immediately above the light-emitting region 108. The microlens 106a is shifted by a shift amount 300a in the direction from the center portion A to the peripheral portion B of the display region 200 (the right direction in FIG. 8; the first direction) relative to the light-emitting region 108 of the light-emitting element 220.

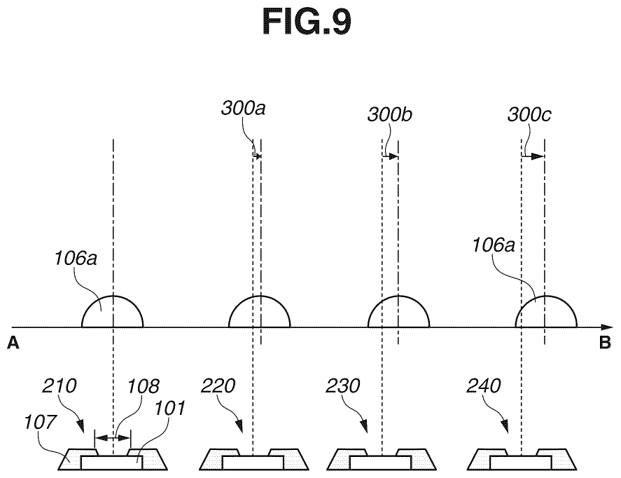

FIG. 9 is a cross-sectional view of a part of a light-emitting apparatus according to comparative example 1. The light-emitting apparatus according to comparative example 1 includes a microlens 106a corresponding one-on-one to each of light-emitting elements 210 to 240. Further, the positional relationship between the microlens 106a and the light-emitting region 108 changes in the direction from A to B.

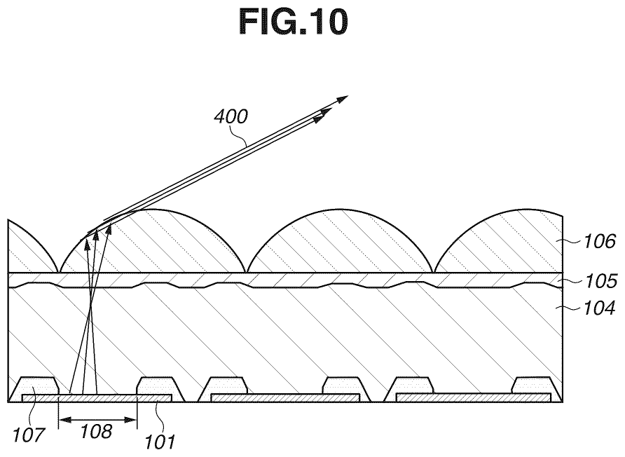

FIG. 10 is an enlarged schematic view of a part of the light-emitting apparatus in FIG. 9. In FIG. 10, the light-emitting apparatus includes a lower electrode 101, an insulating layer 107 that covers both ends of the lower electrode 101, a light-emitting region 108, a protection layer 104, a planarization layer 105, and a microlens 106. On the lower electrode 101, functional layers including a light-emitting layer, an upper electrode, and the like are disposed, but are omitted for convenience. The results of optical simulations are also illustrated together.

In a part of the light-emitting apparatus according to comparative example 1, the microlens 106a is shifted in the direction from the center portion A to the peripheral portion B (the right direction in FIG. 9) relative to the light-emitting region 108 corresponding one-on-one to the microlens 106a. A ray 400 emitted from an optical mechanism to a certain angle on the wide-angle side is emitted only from a part of the light-emitting region 108. That is, it is understood that in light emitted from the light-emitting region 108, light emitted to a wide angle and contributing to viewing is light emitted only from a part of the light-emitting region 108.

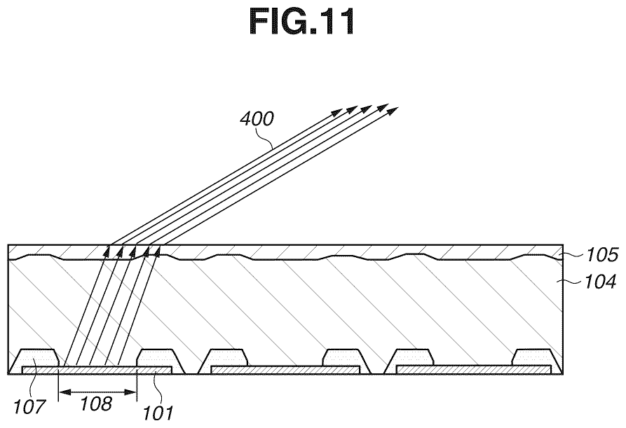

FIG. 11 is an enlarged view of a part of the light-emitting apparatus according to the present embodiment illustrated in FIG. 8. In FIG. 11, the light-emitting apparatus includes a lower electrode 101, an insulating layer 107 that covers both ends of the lower electrode 101, a light-emitting region 108, a protection layer 104, and a planarization layer 105. On the lower electrode 101, functional layers including a light-emitting layer, an upper electrode, and the like are disposed, but are omitted for convenience. The results of optical simulations are also illustrated together.

As can be understood from FIG. 11, a ray 400 emitted from an optical mechanism to a certain angle on the wide-angle side is emitted from a region larger than the entirety or half of the light-emitting region 108. Thus, as in the present embodiment, microlenses 106 corresponding to light-emitting elements are not disposed in the second region 202 as the peripheral portion, whereby it is possible to improve the intensity of light emitted from the optical mechanism to the wide-angle side.

The light-emitting apparatus in FIG. 8 includes the microlens 106a disposed immediately above the light-emitting region 108 of the light-emitting element 210 in the first region 201. The light-emitting apparatus also includes the microlens 106a disposed in a shifted manner by the shift amount 300a in the right direction in FIG. 8 relative to the light-emitting region 108 of the light-emitting element 220 in the first region 201. Thus, similarly to the first and second embodiments, it is possible to increase the intensity of light emitted from the light-emitting mechanism 110 (the microlens 106 in this case) to the wide-angle side.

Further, as illustrated in FIG. 8, the light-emitting apparatus according to the present embodiment does not include microlenses 106 corresponding to the light-emitting elements 230 and 240 in the second region 202. Thus, as can be understood from FIGS. 10 and 11, it is possible to increase the intensity of light emitted from an optical mechanism (a light-emitting element in this case) to the wide-angle side compared to the light-emitting apparatus including the microlens 106a corresponding to each of the light-emitting elements 230 and 240. That is, with the configuration of the light-emitting apparatus according to the present embodiment, it is possible to improve the intensity of light emitted to the wide-angle side in the display region 200.

The second region 202 surrounds the first region 201, whereby it is possible to improve the balance of luminance in the entirety of the display region 200 compared to a case where only a part of the peripheral portion is the second region 202.

Although FIG. 8 illustrates an example where the microlens 106a is placed shifted in the right direction in FIG. 8 (the direction from the center portion A to the peripheral portion B of the display region 200) relative to the light-emitting region 108, the light-emitting apparatus according to the present embodiment is not limited to this configuration. For example, the microlens 106a may be placed shifted in the left direction in FIG. 8 (a direction from the peripheral portion B to the center portion A of the display region 200) relative to the light-emitting region 108.

In the planar view of the main surface of the substrate, the area of the second region 202 may cover 5% to 95% of the area of the display region 200. In a case where the light-emitting mechanism 110 is used with the optical lens 120 as illustrated in FIG. 18A, a configuration may be employed in which a region at which the user cannot gaze by rotating the eyeball 130 is the second region 202, and the microlens 106b is not included. That is, the second region 202 may be disposed at a position at which the user cannot gaze through the optical lens 120 as the eyepiece optical system. At this time, in the planar view, the second region 202 may cover 10% to 40% of the area of the display region 200.

Alternatively, a region at which the user cannot gaze by rotating the eyeball 130 may be the second region 202 and may be a region where the microlens 106 is not disposed. In other words, a configuration may be employed in which the microlens 106 is not disposed in a region at which the user cannot gaze but from which light reaches the eyeball 130. The light-emitting apparatus has the configuration in which the second region 202 does not include the microlens 106, whereby it is possible to prevent a decrease in the luminance of video in the region at which the user cannot gaze but from which light reaches the eyeball 130. Thus, in a case where display is performed using the light-emitting apparatus, it is possible to increase the display quality.

The display region 200 may include a plurality of light-emitting elements including a first light-emitting element and a second light-emitting element, and a plurality of microlenses including a first microlens, and the amount of shift of the first microlens relative to each of the light-emitting elements may differ in the first direction. For example, the following configuration may be employed. Among the plurality of light-emitting elements and the plurality of microlenses, in the planar view of the main surface of the substrate, the further away from the center of the display region 200 and the closer to the end of the display region 200 the vertex of each of the plurality of microlenses is, the more shifted to the end side in the first direction relative to the midpoint of a light-emitting region corresponding to the microlens the vertex may be.

### Fourth Embodiment

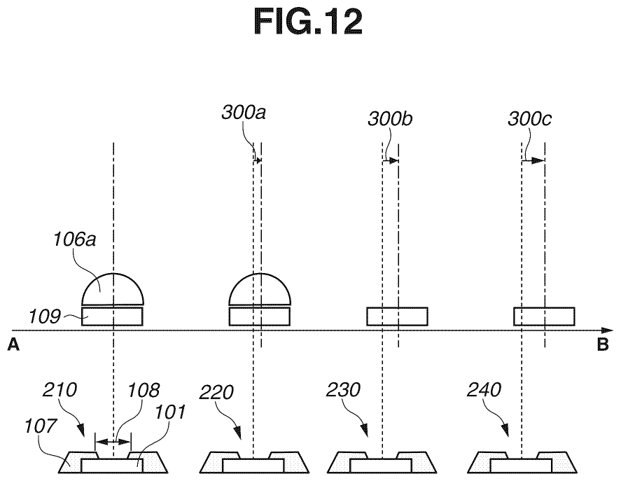

FIG. 12 is a diagram illustrating an example of a light-emitting apparatus according to a fourth embodiment. Structures, functions, materials, effects, and the like similar to those according to any of the first to third embodiments are not described again. FIG. 12 is an example of a cross-sectional view of a part of the light-emitting apparatus along a straight line A-B in FIG. 1A. In this cross section, some light-emitting elements are omitted. The light-emitting apparatus according to the present embodiment includes a color filter 109 in addition to the light-emitting apparatus according to the third embodiment.

The display region 200 of the light-emitting apparatus according to the present embodiment includes a first region 201, and a second region 202 that is closer to the end of the display region 200 than the first region 201 is. The light-emitting apparatus includes a first light-emitting element disposed on the main surface of the substrate, a first lens disposed on the first light-emitting element and corresponding one-on-one to the first light-emitting element, and a first color filter disposed on the first light-emitting element and corresponding one-on-one to the first light-emitting element in the first region 201. The light-emitting apparatus also includes a second light-emitting element disposed on the main surface and a second color filter disposed on the second light-emitting element and corresponding one-on-one to the second light-emitting element in the second region 202.

A color filter corresponding one-on-one to a certain light-emitting element refers to a color filter that overlaps a light-emitting region such that the area of the overlap is less than or equal to the area of the light-emitting region in the planar view of the main surface.

In the planar view of the main surface of the substrate, the distance in the first direction between the midpoint of a light-emitting region of the second light-emitting element and the midpoint of the second color filter is greater than the distance in the first direction between the midpoint of a light-emitting region of the first light-emitting element and the midpoint of the first color filter. Each of the midpoint of the light-emitting region and the midpoint of the color filter may be the midpoint in the first direction. That is, the amount of shift between the light-emitting region 108 and the color filter 109 disposed in the second region 202 is greater than the amount of shift between the light-emitting region 108 and the color filter 109 disposed in the first region 201.

With reference to FIG. 12, a more specific configuration is described. In the first region 201, a microlens 106a corresponding one-on-one to each of a light-emitting element 210 and a light-emitting element 220 is disposed. A color filter 109 (a first color filter) is disposed between the light-emitting element 210 and the microlens 106a, and a color filter 109 (a first color filter) is disposed between the light-emitting element 220 and the microlens 106a. On the other hand, in the second region 202, a color filter 109 corresponding one-on-one to each of a light-emitting element 230 and a light-emitting element 240 is disposed, but the microlens 106 is not disposed.

Although not illustrated, the light-emitting apparatus may include a reflection layer and an insulating layer with respect to each light-emitting element, and an optical resonance structure may be constructed between the reflection layer and an upper electrode disposed through a lower electrode and an organic layer.

Further, the positional relationship between the color filter 109 and the microlens 106, and the light-emitting region 108 changes in the direction from A to B. A specific description is given based on the positional relationship between the light-emitting region 108 of the light-emitting element 210, and the color filter 109 and the microlens 106a disposed immediately above the light-emitting region 108. In the present embodiment, the color filter 109 and the microlens 106a are disposed in a shifted manner by a shift amount 300a in the direction from the center portion A to the peripheral portion B of the display region 200 (the right direction in FIG. 12) relative to the light-emitting region 108 of the light-emitting element 220.

Similarly, in the second region 202, the color filter 109 is disposed in a shifted manner by a shift amount 300b in the direction from the center portion A to the end of the display region 200 relative to the light-emitting region 108 of the light-emitting element 230. Further, the color filter 109 is disposed in a shifted manner by a shift amount 300c in the direction from the center portion A to the end of the display region 200 relative to the light-emitting region 108 of the light-emitting element 240.

Also in the present embodiment, similarly to the third embodiment, microlenses 106 corresponding to the light-emitting elements 230 and 240 are not disposed in the second region 202, whereby it is possible to improve the intensity of light emitted from the optical mechanism to the wide-angle side.

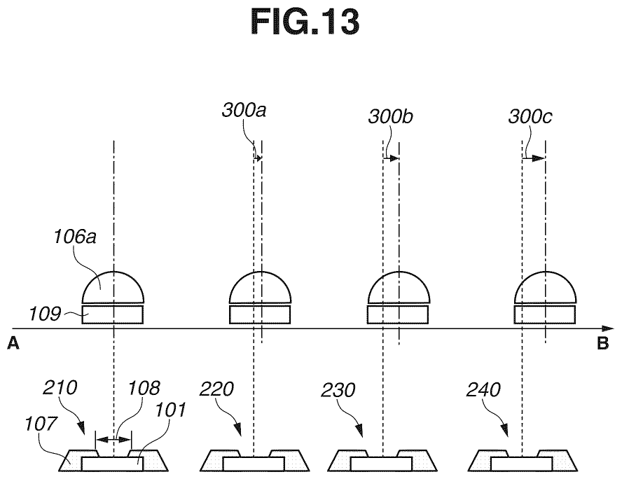

FIG. 13 is a cross-sectional view of a part of a light-emitting apparatus according to comparative example 2. The light-emitting apparatus according to comparative example 2 includes a color filter 109 and a microlens 106a corresponding one-on-one to each of light-emitting elements 210 to 240. Further, the positional relationship between the color filter 109 and the light-emitting region 108 changes in the direction from A to B. The positional relationship between the microlens 106a and the light-emitting region 108 also changes in the direction from A to B.

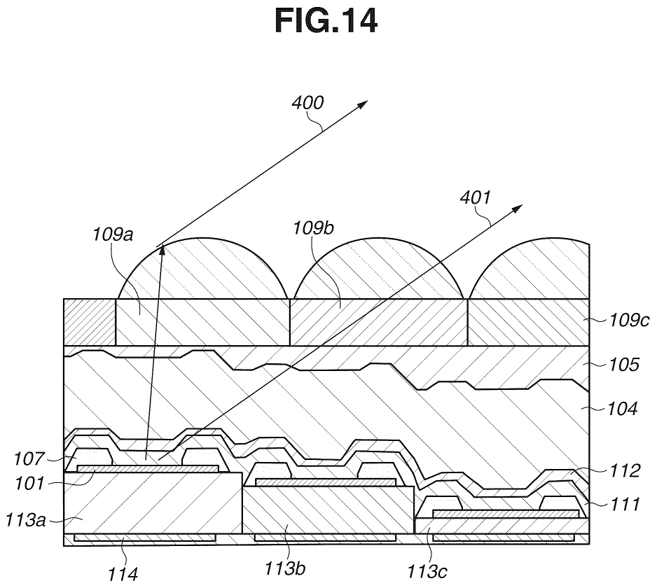

FIG. 14 is an enlarged schematic view of a part of the light-emitting apparatus in FIG. 13. In FIG. 14, the light-emitting apparatus includes a reflection layer 114, an insulating layer 113, a lower electrode 101 disposed on the reflection layer 114 through the insulating layer 113, an insulating layer 107 that covers both ends of the lower electrode 101, an organic layer 111, and an upper electrode 112. The light-emitting apparatus also includes a protection layer 104, a planarization layer 105, color filters 109a to 109c, and microlenses 106 disposed on the upper electrode 112.

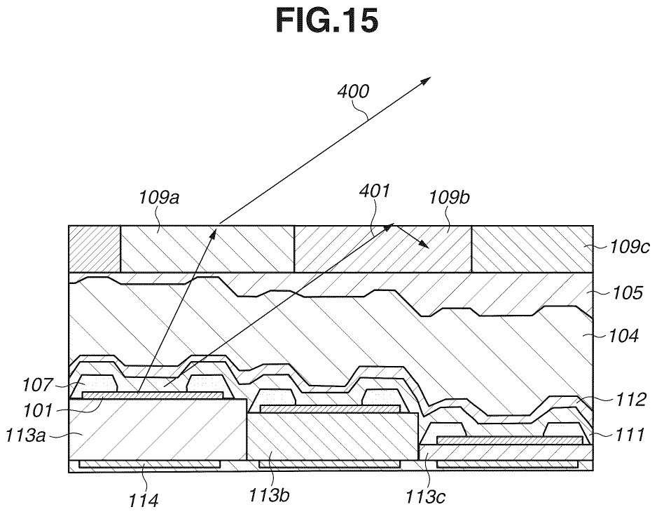

FIG. 15 is an enlarged view of the light-emitting element 240 in FIG. 12 illustrating an example of the present embodiment. In FIG. 15, the light-emitting apparatus includes a reflection layer 114, an insulating layer 113, a lower electrode 101 disposed on a reflection layer 114 through the insulating layer 113, an insulating layer 107 that covers both ends of the lower electrode 101, an organic layer 111, and an upper electrode 112. The light-emitting apparatus also includes a protection layer 104, a planarization layer 105, and color filters 109a to 109c disposed on the upper electrode 112, but does not include microlenses 106 in the second region 202.

In a case where the optical distance between the upper surface of the reflection layer 114 and the light-emitting position of the organic layer 111 in the light-emitting element 240 is optimized with respect to each color, the following formula (1) holds. The optical path length from the upper surface of the reflection layer 114 to the light-emitting position of the organic layer 111 is an optical path length Lr, a phase shift in the reflection layer 114 is a phase shift Ør, and the wavelength of light is 2.

$$Lr = ( 2 m - ( Φ r / π ) ) \times ( λ / 4 ) \pm λ / 12 \qquad ( 1 )$$

Here, m is an integer greater than or equal to 0. The optical distances of insulating layers 113a to 113c are distances satisfying the above formula (1) on a color-by-color basis, whereby it is possible to increase the intensity of light emitted through each of the insulating layers 113a to 113c.

In a case where an optical distance Ls from the light-emitting position to a reflection surface of the upper electrode 112 is optimized with respect to each color, the following formula (2) holds. The optical distance from the light-emitting position to the reflection surface of the upper electrode 112 is an optical distance Ls, and a phase shift when light having the wavelength 2 is reflected by the reflection surface is a phase shift Φs. In this configuration, m′=0.

$$Ls = ( 2 {m}^{′} - ( Φ s / π ) ) \times ( λ / 4 ) \pm λ / 12 = - ( Φ s / π ) \times ( λ / 4 ) \pm λ / 12 \qquad ( 2 )$$

Thus, an all-layers interference L may satisfy the following formula (3).

$$L = Lr + L = ( 2 m - Φ / π ) \times ( λ / 4 ) \pm λ / 12 \qquad ( 3 )$$

In formula (3), Φ is a sum Φr+Φs of the phase shifts when light having the wavelength λ is reflected by the reflection layer 114 and the upper electrode 112.

In the light-emitting apparatus, each of a plurality of pixels may include a plurality of sub-pixels. The sub-pixels may emit different colors. For example, each pixel may include three sub-pixels that emit light of three colors, namely red (R), green (G), and blue (B). Each pixel may further include a sub-pixel that emits white light in addition to R, G, and B. A configuration in which three sub-pixels include color filters 109a, 109b, and 109c is used as an example. A configuration in which a certain sub-pixel includes a color filter 109 may be a configuration in which light emitted from a light-emitting region of the sub-pixel mainly passes through the color filter 109.

The planar arrangement of sub-pixels may be any of methods including stripe arrangement, square arrangement, delta arrangement, and Bayer arrangement. Main pixels are placed in a matrix, whereby it is possible to achieve a display apparatus having a large number of pixels.

In comparative example 2 illustrated in FIG. 14, the color filters 109a to 109c and the microlenses 106 are shifted in the right direction in FIG. 14 (the first direction; the direction from the center portion A to the peripheral portion B of the display region 200). A ray 400 emitted to a certain angle on the wide-angle side at this time passes through the color filter 109a and is emitted by the microlens 106 changing the angle of the ray 400. Then, a ray 401 emitted further to the wide-angle side passes through the color filter 109b, passes through the microlens 106, and is emitted as it is. When a single light-emitting region 108 emits light, light passing through the color filter 109a and light passing through the color filter 109b are both emitted. Thus, light of different colors is emitted, and color mixture occurs.

In FIG. 15 illustrating an example of a part of the light-emitting apparatus according to the present embodiment, a ray 400 emitted to a certain angle on the wide-angle side passes through the color filter 109a and is emitted. On the other hand, a ray 401 emitted further to the wide-angle side is totally reflected by the interface between the color filter 109b and air or an insulating layer (not illustrated) made of a resin or the like on the color filter 109b, and therefore is not emitted from the light-emitting mechanism. The refractive index of the insulating layer (including the air layer) on the color filter 109b with respect to light emitted from a light-emitting element is smaller than the refractive index of the color filter 109b. Thus, in the present embodiment, it is possible to prevent color mixture on the wide-angle side in light emitted from a light-emitting element disposed in the second region 202.

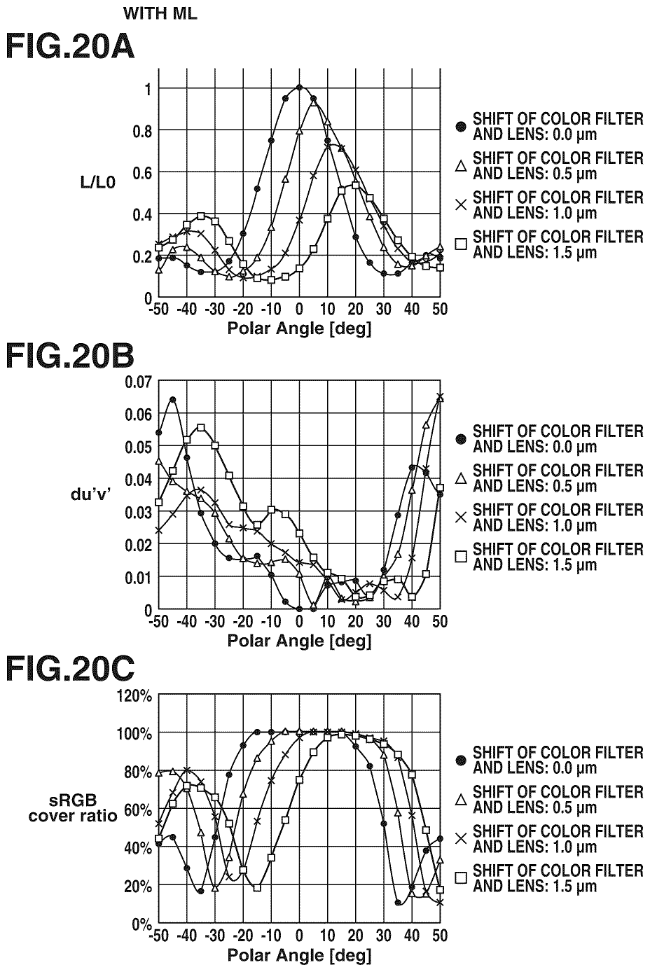

FIGS. 20A to 20C illustrate viewing angle characteristics in a case where a microlens 106 corresponding one-on-one to a light-emitting element is disposed and when the amount of shift of the microlens 106 and the color filter 109 in the first direction relative to the light-emitting element is 0 μm, 0.5 μm, 1.0 μm, and 1.5 μm.

In FIG. 20A, the horizontal axis represents the exit angle of light emitted from the light-emitting region 108 of the light-emitting element, and the vertical axis represents the actual measured value of the ratio of the luminance of emitted light in each case to the luminance of emitted light when the exit direction of light is 0° and the microlens 106 is not shifted relative to the light-emitting element (the luminance ratio). In FIG. 20B, the horizontal axis represents the exit angle of light emitted from the light-emitting region 108 of the light-emitting element, and the vertical axis represents the actual measured value of the difference between the chromaticity of emitted light in each case and the chromaticity of emitted light when the exit direction of light is 0° and the microlens 106 is not shifted relative to the light-emitting element (the chromaticity difference). In FIG. 20C, the horizontal axis represents the exit angle of light emitted from the light-emitting region 108 of the light-emitting element, and the vertical axis represents the actual measured value of the sRGB cover rate of emitted light in each case.

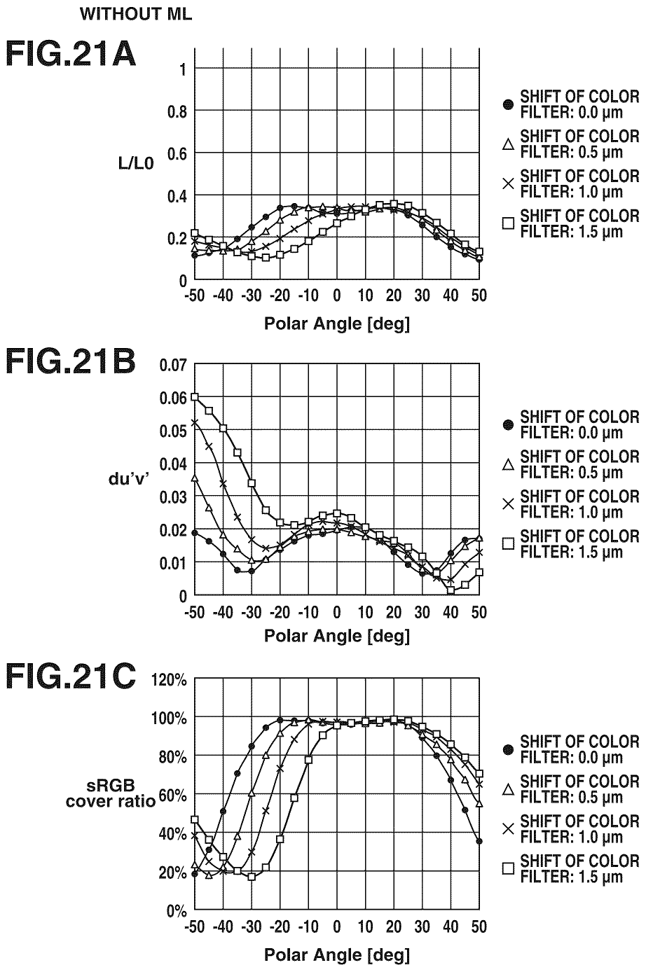

FIGS. 21A to 21C illustrate viewing angle characteristics in a case where the microlens 106 is not disposed and when the amount of shift of the color filter 109 in the first direction relative to the light-emitting element is 0 μm, 0.5 μm, 1.0 μm, and 1.5 μm. Also in each of FIGS. 21A to 21C, the horizontal axis represents the exit angle of light emitted from the light-emitting region 108 of the light-emitting element.

FIG. 21A illustrates the actual measured value of the ratio of the luminance of emitted light in each case to the luminance of emitted light in a case where the exit direction of light is 0° and the microlens 106 disposed corresponding one-on-one to the light-emitting element without an amount of shift is included (the luminance ratio). FIG. 21B illustrates the actual measured value of the difference between the chromaticity of emitted light in each case and the chromaticity of emitted light when the exit direction of light is 0° and the color filter 109 is not shifted relative to the light-emitting element (the chromaticity difference). Further, FIG. 21C illustrates the actual measured value of the sRGB cover rate of emitted light in each case.

In FIGS. 20A to 20C and 21A to 21C, measurements were made using spectroradiometer SR-5A manufactured by TechnoOptis Co., Ltd.

For example, as illustrated in FIGS. 18A and 18B, light often used in the light-emitting apparatus that uses light emitted to the wide-angle side using the optical lens 120 has an exit angle of 40°.

Thus, light having an exit angle of 40° is considered below.

From FIGS. 20A and 21A, the luminance is greater, although slightly, in a case where the microlens 106 is not disposed and the color filter 109 is disposed in a shifted manner than in a case where the microlens 106 corresponding to the light-emitting element is disposed in a shifted manner. From FIGS. 20B and 21B, the chromaticity difference of emitted light is further reduced in a case where the microlens 106 is not disposed and the color filter 109 is disposed in a shifted manner than in a case where the microlens 106 corresponding to the light-emitting element is disposed in a shifted manner.

From FIGS. 20C and 21C, the sRGB cover rate is more improved in a case where the microlens 106 is not disposed and the color filter 109 is disposed in a shifted manner than in a case where the microlens 106 corresponding to the light-emitting element is disposed in a shifted manner. That is, color mixture of light on the wide-angle side is prevented in light emitted from the light-emitting element, whereby it is possible to reduce the chromaticity difference and improve the sRGB cover rate.

Although at this time, in FIG. 12, the microlens 106a and the color filter 109 are placed shifted in the direction from the center portion A to the peripheral portion B (the first direction; the right direction in FIG. 12) relative to the light-emitting element, the configuration of the light-emitting apparatus according to the present embodiment is not limited to this. The microlens 106a and the color filter 109 may be placed shifted in a direction from the peripheral portion B to the center portion A (the left direction in FIG. 12) relative to the light-emitting element. In other words, the color filter 109 and the microlens 106a may be placed shifted in the central direction of the display region 200 relative to the light-emitting element.

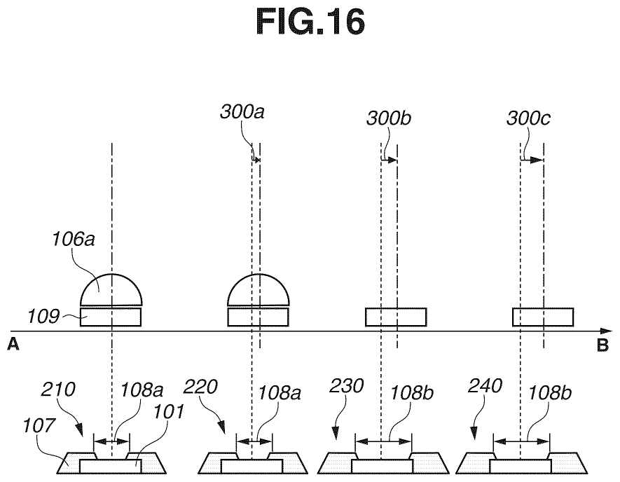

Alternatively, as illustrated in FIG. 16, a light-emitting region 108b of each of the light-emitting elements 230 and 240 located in the second region 202 may be larger than a light-emitting region 108a of each of the light-emitting elements 210 and 220 located in the first region 201. Due to the presence of the microlens 106 in the first region 201, it is possible to increase the current efficiency by making the light-emitting region 108 small. Thus, it is possible to reduce power consumption.

On the other hand, in each of the light-emitting elements 230 and 240, the current density is lowered by making the light-emitting region 108 large. In a case where the microlens 106 is disposed on the exit side of light, the area where emitted light is effectively extracted in the light-emitting region 108 is smaller than in a case where the microlens 106 is not disposed. Since microlenses 106 corresponding to the light-emitting elements 230 and 240 are not disposed, even if the light-emitting regions 108 are made large, it is possible to effectively emit emitted light from the light-emitting mechanism. Thus, it is possible to reduce the current density while maintaining the luminance of effective light emitted from the light-emitting mechanism. The current density is reduced, whereby it is possible to reduce the deterioration of the luminance of a light-emitting element.

The color filter 109 can also be disposed in any of the first to third embodiments, and any of the first to third embodiments can be appropriately combined with the present embodiment. Consequently, it is possible to obtain the effects described in the present embodiment.

### Fifth Embodiment

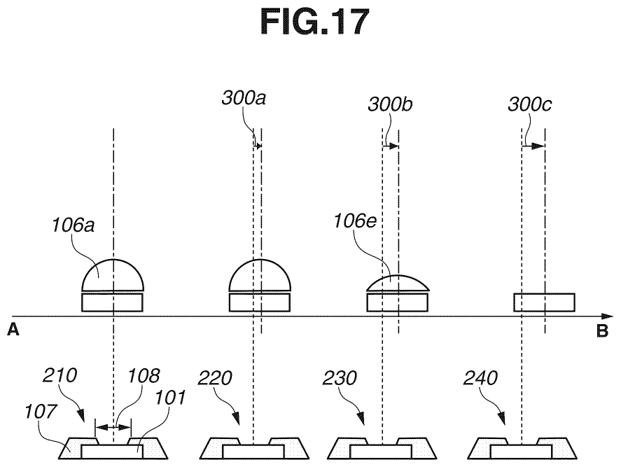

FIG. 17 is a diagram illustrating an example of a light-emitting apparatus according to a fifth embodiment. FIG. 17 is an example of a part of a cross-sectional view along a straight line A-B in FIG. 7A. The light-emitting apparatus according to the present embodiment includes a third region 203 disposed between the first region 201 and the second region 202 in the first direction in the planar view of the main surface of the substrate. The light-emitting apparatus according to the present embodiment also includes a third light-emitting element disposed on the main surface and a third lens disposed on the third light-emitting element and corresponding one-on-one to the third light-emitting element in the third region 203. The focal length of the third lens is longer than the focal length of the first lens disposed in the first region 201.

With reference to FIG. 17, a more specific configuration is described. In the first region 201, a microlens 106a having a short focal length and corresponding one-on-one to each of a light-emitting element 210 and a light-emitting element 220 is disposed, and in the second region 202, the microlens 106 is not disposed. The third region 203 includes a microlens 106e corresponding one-on-one to a light-emitting element 230, and the microlens 106e has a longer focal length than that of the microlens 106a.

The positional relationship between the microlens 106e and the light-emitting region 108 changes in the direction from A to B in the third region 203. A specific description is given based on the positional relationship between the light-emitting region 108 of the light-emitting element 210 and the microlens 106a disposed immediately above the light-emitting region 108. The microlens 106e is shifted by a shift amount 300b in the direction from the center portion A to the peripheral portion B of the display region 200 (the right direction in FIG. 17) relative to the light-emitting region 108 of the light-emitting element 230.

The third region 203 including the microlens 106e is provided between the first region 201 and the second region 202, whereby it is possible to moderate a change in the luminance between the first region 201 and the second region 202 and increase the display quality.

Next, a method for manufacturing the microlens 106 according to the present embodiment is described. A case is described where the microlenses 106a and 106b or the microlenses 106a and 106c are simultaneously manufactured by a gradation exposure method.

As an example of the gradation exposure method, a case is described where an area gradation mask is used. The area gradation mask is a method for creating gradation in exposure light by changing the density of minute light-blocking portions having a size that cannot be achieved by an exposure apparatus alone, or changing the areas of the minute light-blocking portions. However, as the gradation exposure method, another mask such as a halftone mask or the like may be used. The microlenses 106a and 106b may not necessarily need to be manufactured by the gradation exposure method, and for example, may be manufactured using a reflow method or an etch-back method.

First, until the insulating layer 107 illustrated in FIG. 10 or 14 is formed, the light-emitting apparatus can be formed using a known semiconductor process. After the insulating layer 107 is formed, the organic layer 111 is formed on the electrode 101 using a vapor deposition method. In an electron injection layer in the organic layer 111, lithium fluoride may be used. After the organic layer 111 is formed, the upper electrode 112 is formed by co-evaporating silver (Ag) and magnesium (Mg) at a ratio of 1:1.

Then, a silicon nitride (SiN) film is formed as the protection layer 104 using a chemical vapor deposition (CVD) method, and further, an acrylic resin is applied as the planarization layer 105 by spin coating. The color filter 109 may be formed as illustrated in FIG. 14. Alternatively, the upper surface of the color filter 109 may be planarized.

Further, a lens material layer using a photosensitive organic material (a photosensitive material layer) is formed. For example, a photosensitive resin is applied as the lens material layer using the spin coating method. Although an example where the photosensitive resin is of the negative type is described below, the photosensitive resin of the positive type may be used. After the lens material layer is formed, any portion of the lens material layer is exposed using the area gradation mask on the lens material layer, and the lens material layer is developed and baked. Thereafter, ultraviolet irradiation is performed to form the microlens 106.

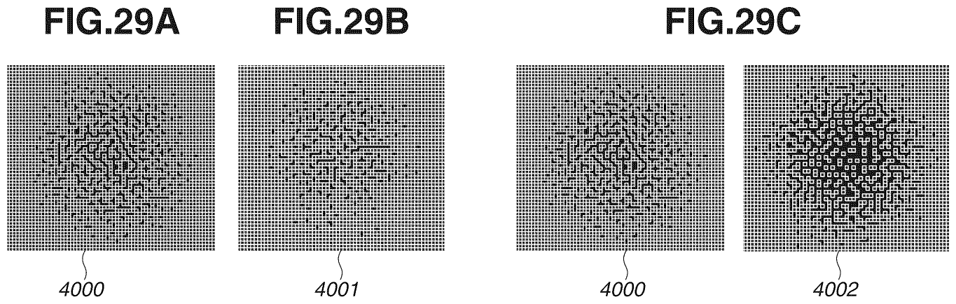

FIG. 29A illustrates an example of an area gradation pattern 4000 for forming the microlens 106a and placed in the area gradation mask. FIG. 29B illustrates an example of an area gradation pattern 4001 for forming the microlens 106b and placed in the area gradation mask. Further, FIG. 29C illustrates an example of an area gradation pattern 4002 for forming the microlens 106c and placed in the area gradation mask. A black portion transmits light, and a white portion indicates a light-blocking portion that blocks light.

The area gradation pattern 4001 is an area gradation pattern having more overall white portions, i.e., a higher density of light-blocking portions, than the area gradation pattern 4000. Thus, in the area gradation pattern 4001, the transmission amount of light decreases overall, and the use of the photosensitive resin of the negative type can make the distance from the vertex to the lower surface small as in the microlens 106b. That is, it is possible to make the radius of curvature large as in the microlens 106b.

The area gradation pattern 4002 is an area gradation pattern having fewer overall white portions, i.e., a lower density of light-blocking portions, than the area gradation pattern 4000. Thus, in the area gradation pattern 4002, the transmission amount of light increases overall, and the use of the photosensitive resin of the negative type can make the height great, i.e., make the distance from the vertex to the lower surface great, as in the microlens 106c. At this time, a reduction in outer white portions, i.e., the lowering of the density of outer light-blocking portions, as in the area gradation pattern 4002 can make the outer height of the microlens 106 great. Thus, it is possible to make the radius of curvature large as in the microlens 106c.

The area gradation pattern 4000 is placed in the first region 201, and the area gradation pattern 4001 is placed in the second region 202, whereby it is possible to form the microlenses 106a and 106b with a single area gradation mask. Alternatively, the microlenses 106a and 106b may be formed using two or more area gradation masks.

In a case where the microlenses 106a and 106b are formed using two area gradation masks, it is possible to use a first mask in which the area gradation pattern 4000 is disposed in the first region 201 and the second region 202 is shielded from light, and a second mask in which the area gradation pattern 4001 is disposed in the second region 202 and the first region 201 is shielded from light.

After the photosensitive resin is applied as the lens material layer using the spin coating method, the microlens in the first region 201 is exposed using the first mask, the microlens in the second region 202 is exposed, developed, and baked using the second mask. Then, the microlens 106 is formed by performing ultraviolet irradiation.

In a case where the microlenses 106a and 106b are formed using a single area gradation mask, it is possible to reduce the number of steps, and it is possible to reduce manufacturing cost. In a case where two or more area gradation masks are used, the number of steps increases, but it is possible to adjust the shapes of microlenses to be formed by the exposure conditions.

By the above steps, the microlenses 106a and 106b or the microlenses 106a and 106c are formed.

Next, with reference to the drawings, a display apparatus according to the present embodiment is described.

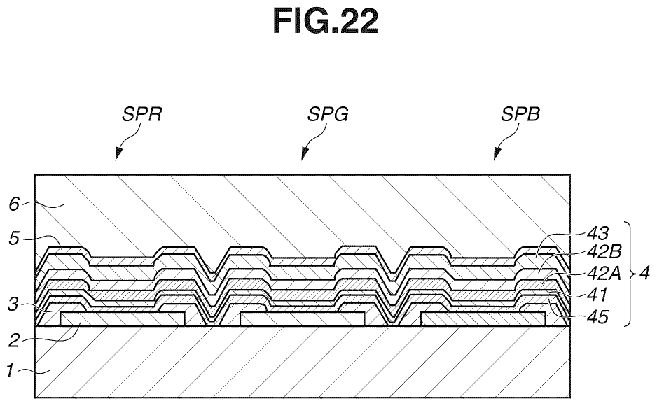

FIG. 22 is a schematic cross-sectional view illustrating an example of a semiconductor apparatus including an organic light-emitting element and a transistor connected to the organic light-emitting element. The transistor is an example of an active element. Although an example is illustrated where the transistor is a thin-film transistor (TFT), a metal-oxide-semiconductor field-effect transistor (MOSFET) using a semiconductor substrate can also be used. Through the use of a MOSFET, it is possible to dispose a transistor in each pixel in the placement based on the above embodiments within a smaller area.

FIG. 22 is an example of a pixel as a component of the semiconductor apparatus according to the present embodiment. The pixel includes a sub-pixel SP. The sub-pixel SP is divided into sub-pixels SPR, SPG, and SPB based on light emission from the sub-pixel SP. The light emission colors may be distinguished based on wavelengths at which light is emitted from a light-emitting layer, or light emitted from the sub-pixel SP may be further selectively transmitted or subjected to color conversion using a color filter or the like. In each of the sub-pixels SPR, SPG, and SPB, the semiconductor apparatus includes a lower electrode 2, an insulating layer 3 that covers the ends of the lower electrode 2, a functional layer 4 that covers the lower electrode 2 and the insulating layer 3, a second electrode 5, and an insulating layer 6 on an element substrate 1.

On a layer below the element substrate 1 or within the element substrate 1, a transistor and a capacitor element may be disposed. The transistor and the lower electrode 2 may be electrically connected together via a contact hole (not illustrated) or the like.

The insulating layer 3 is also referred to as a “bank” or a “pixel separation film”. The insulating layer 3 covers the ends of the lower electrode 2 and is disposed around the lower electrode 2. A portion where the insulating layer 3 is not disposed is in contact with the functional layer 4 and forms a light emission area.

The functional layer 4 includes a hole injection layer 45, a hole transport layer 41, a first light-emitting layer 42A, a second light-emitting layer 42B, and an electron transport layer 43.

The second electrode 5 may be a transparent electrode or a semi-transmissive electrode.

The insulating layer 6 reduces the penetration of moisture into the functional layer 4. Although the insulating layer 6 is illustrated as a single layer in FIG. 22, the insulating layer 6 may include a plurality of layers. Each layer may be an inorganic compound layer or an organic compound layer.

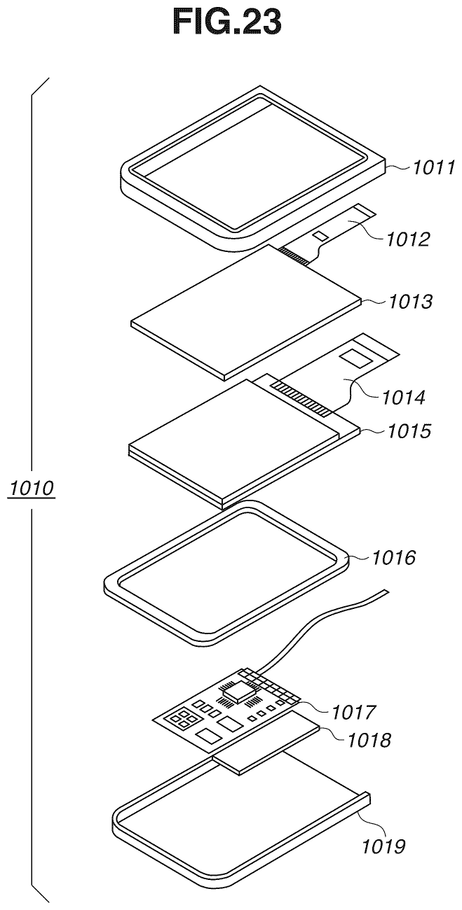

FIG. 23 is a schematic view illustrating a display apparatus as an example of the semiconductor apparatus. A display apparatus 1010 may include a touch panel 1013, a display panel 1015, a frame 1016, a circuit board 1017, and a battery 1018 between an upper cover 1011 and a lower cover 1019. The touch panel 1013 and the display panel 1015 are connected to flexible printed circuits (FPCs) 1012 and 1014, respectively.

The display panel 1015 includes the light-emitting apparatus according to at least any one of the first to fifth embodiments. On the circuit board 1017, a transistor is printed. The battery 1018 may not be provided unless the display apparatus 1010 is a mobile device, or may be provided at another position even if the display apparatus 1010 is a mobile device.

The display apparatus according to the present embodiment may also be used in a display unit of a mobile terminal. At this time, the display apparatus may have both a display function and an operation function. Examples of the mobile terminal include a mobile phone such as a smartphone or the like, a tablet, a head-mounted display, and the like.

The display apparatus according to the present embodiment may also be used in a display unit of an imaging apparatus including an optical unit that includes a plurality of lenses, and an imaging element that receives light passing through the optical unit. The imaging apparatus may include a display unit that displays information acquired by the imaging element. The display unit may be a display unit exposed to outside the imaging apparatus, or may be a display unit placed in a viewfinder. The imaging apparatus may be a digital camera or a digital video camera.

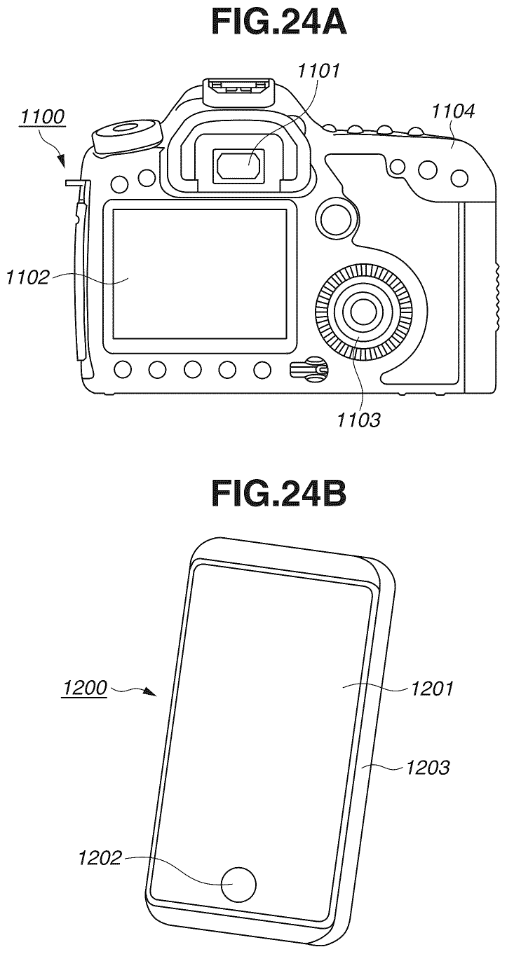

FIG. 24A is a schematic view illustrating an example of an imaging apparatus as an application example of the semiconductor apparatus according to the present embodiment. An imaging apparatus 1100 may include a viewfinder 1101, a back surface display 1102, an operation unit 1103, and a housing 1104. The viewfinder 1101 may include the light-emitting apparatus according to at least any one of the first to fifth embodiments as a display. In this case, the organic light-emitting apparatus may display not only a captured image, but also environment information, an imaging instruction, and the like. The environment information may include the intensity of external light, the direction of external light, the moving speed of an object, the possibility that an object is blocked by a blocking object, and the like.

Since a timing suitable for capturing an image lasts for a short time, it is desirable that the information be displayed as quickly as possible. Thus, it is desirable to use the light-emitting apparatus according to any of the first to fifth embodiments using the organic light-emitting element. This is because the response speed of the organic light-emitting element is fast. In the display apparatus, which requires a fast display speed, the light-emitting apparatus according to any of the first to fifth embodiments can be used more suitably than a liquid crystal display apparatus.

The imaging apparatus 1100 includes an optical unit (not illustrated). The optical unit includes a plurality of lenses and forms an image on an imaging element accommodated in the housing 1104. The focus can be adjusted by adjusting the relative positions of the plurality of lenses. This operation can also be performed automatically. The imaging apparatus 1100 may also be referred to as a “photoelectric conversion apparatus”. The photoelectric conversion apparatus can include a method for detecting the difference from the previous image without sequentially capturing images, a method for clipping an image from an always recorded image, or the like as an imaging method.

FIG. 24B is a schematic view illustrating an example of an electronic device according to the present embodiment. An electronic device 1200 includes a display unit 1201, an operation unit 1202, and a housing 1203. The housing 1203 may include a circuit, a printed substrate including the circuit, a battery, and a communication unit.

The display unit 1201 may include the light-emitting apparatus according to at least any one of the first to fifth embodiments. The operation unit 1202 may be a button, or may be a response unit using a touch panel method. The operation unit 1202 may be a biometric unit that recognizes a fingerprint and for example, releases a lock. The electronic device 1200 including the communication unit can also be said to be a communication device. The electronic device 1200 may further have a camera function by including a lens and an imaging element. An image captured by the camera function is displayed on the display unit 1201. Examples of the electronic device 1200 include a smartphone, a laptop personal computer, and the like.

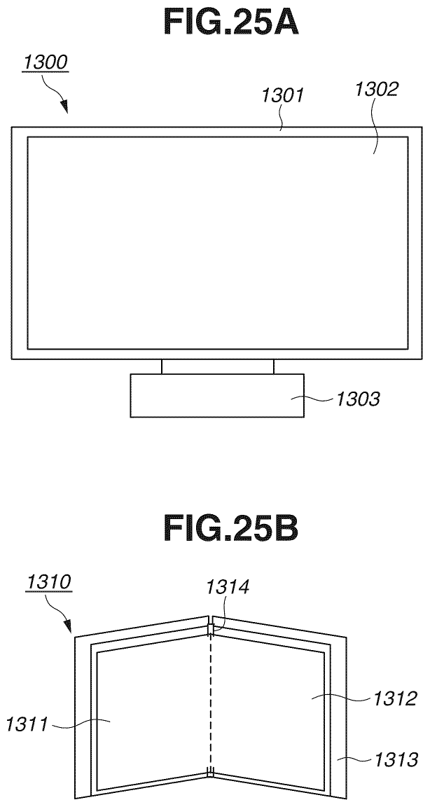

FIGS. 25A and 25B are schematic views illustrating examples of the display apparatus according to the present embodiment. FIG. 25A illustrates a display apparatus 1300 such as a television monitor, a personal computer (PC) monitor, or the like. The display apparatus 1300 includes a frame 1301 and a display unit 1302 surrounded by the frame 1301. The light-emitting apparatus according to at least any one of the first to fifth embodiments may be used in the display unit 1302.

The display apparatus 1300 further includes a base 1303 that supports the frame 1301 and the display unit 1302. The base 1303 is not limited to the form in FIG. 25A. For example, the lower side of the frame 1301 may serve as a base.

The frame 1301 and the display unit 1302 may be curved. The radius of curvature of the curve may be 5000 millimeters (mm) or more and 6000 mm or less.

FIG. 25B is a schematic view illustrating another example of the display apparatus according to the present embodiment. A display apparatus 1310 in FIG. 25B is configured to be folded and is a so-called foldable display apparatus. The display apparatus 1310 includes a first display unit 1311, a second display unit 1312, a housing 1313, and a folding point 1314. The first display unit 1311 and the second display unit 1312 may include the light-emitting apparatus according to at least any one of the first to fifth embodiments. The first display unit 1311 and the second display unit 1312 may be a single display apparatus without a joint. The first display unit 1311 and the second display unit 1312 can be divided at the folding point 1314. The first display unit 1311 and the second display unit 1312 may display images different from each other, or may display a single image.

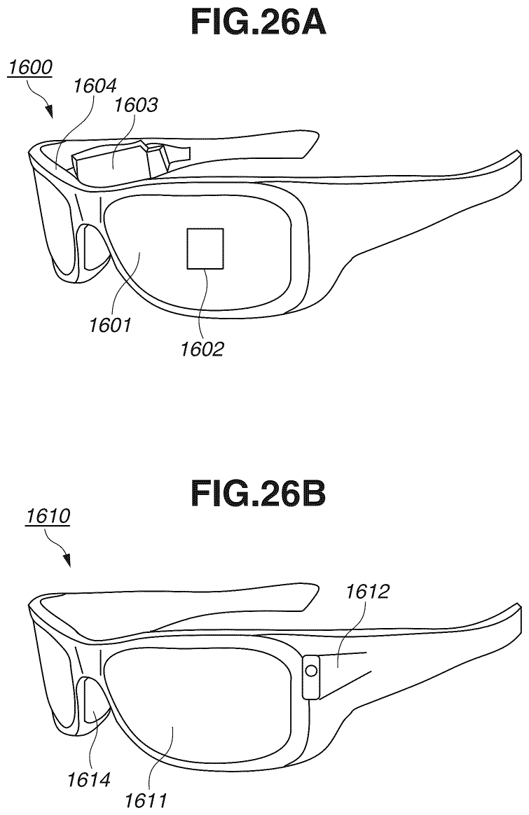

With reference to FIGS. 26A and 26B, an application example of a display apparatus including the light-emitting apparatus according to any of the first to fifth embodiments is described. The display apparatus can be applied to a system that can be worn as a wearable device such as smart glasses, a head-mounted display (HMD), or smart contact lenses. An imaging apparatus and a display apparatus used in such application examples can be an imaging apparatus capable of photoelectrically converting visible light and a display apparatus capable of emitting visible light.

FIG. 26A illustrates eyeglasses 1600 (smart glasses) according to an application example. On the front surface side of a lens 1601 of the eyeglasses 1600, an imaging apparatus 1602 such as a complementary metal-oxide-semiconductor (CMOS) sensor or a single-photon avalanche diode (SPAD) is provided. On the back surface side of the lens 1601, a display apparatus 1604 including the light-emitting apparatus according to at least any one of the first to fifth embodiments is provided.

The eyeglasses 1600 further include a control apparatus 1603. The control apparatus 1603 functions as a power supply that supplies power to the imaging apparatus 1602 and the display apparatus 1604. The control apparatus 1603 controls the operations of the imaging apparatus 1602 and the display apparatus. In the lens 1601, an optical system for collecting light on the imaging apparatus 1602 is formed.

FIG. 26B illustrates eyeglasses 1610 (smart glasses) according to an application example. The eyeglasses 1610 include a control apparatus 1612. On the control apparatus 1612, an imaging apparatus equivalent to the imaging apparatus 1602 and a display apparatus 1614 equivalent to the display apparatus 1604 are mounted. In a lens 1611, an optical system for projecting light emitted from the display apparatus 1614 in the control apparatus 1612 is formed. An image is projected onto the lens 1611. The control apparatus 1612 functions as a power supply that supplies power to the imaging apparatus and the display apparatus 1614, and also controls the operations of the imaging apparatus and the display apparatus 1614.

The control apparatus 1612 may also include a line-of-sight detection unit that detects the line of sight of a wearer (a user). The line of sight may be detected using infrared light. An infrared light-emitting unit emits infrared light to the eyeball of the user gazing at a display image. An imaging unit including a light-receiving element detects reflected light of the emitted infrared light from the eyeball, thereby obtaining a captured image of the eyeball. The control apparatus 1612 includes a reduction unit that reduces light from the infrared light-emitting unit to a display unit in a planar view, thereby reducing a decrease in the quality of the image.

The line of sight of the user to the display image is detected from the captured image of the eyeball obtained by capturing the infrared light. Any known technique can be applied to the line-of-sight detection using the captured image of the eyeball. As an example, a line-of-sight detection method based on a Purkinje image formed by the reflection of emitted light from the cornea can be used.

More specifically, a line-of-sight detection process based on a pupil-corneal reflection method is performed. Using the pupil-corneal reflection method, a line-of-sight vector indicating the direction (the rotation angle) of the eyeball is calculated based on an image of the pupil and a Purkinje image included in the captured image of the eyeball, thereby detecting the line of sight of the user.

The eyeglasses 1610 according to the embodiment may include an imaging apparatus including a light-receiving element and control the display image on the display apparatus 1614 based on line-of-sight information regarding the user from the imaging apparatus.

Specifically, based on the line-of-sight information, the display apparatus 1614 determines a first display region gazed at by the user and a second display region other than the first display region. The first and second display regions may be determined by the control apparatus 1612 of the eyeglasses 1610, or the display apparatus 1614 may receive the first and second display regions determined by an external control apparatus. In a display region of the display apparatus 1614, the display resolution of the first display region may be controlled to be higher than the display resolution of the second display region. That is, the resolution of the second display region may be set to be lower than that of the first display region.

The display region includes the first display region and the second display region different from the first display region, and a region having high priority is determined between the first and second display regions based on the line-of-sight information. The first and second display regions may be determined by a control apparatus of the display apparatus 1614, or the display apparatus 1614 may receive the first and second display regions determined by an external control apparatus. The resolution of the region having high priority may be controlled to be higher than the resolution of the region other than the region having high priority. That is, the resolution of a region having relatively low priority may be set to be low.

The first display region and a region having high priority may be determined using artificial intelligence (AI). The AI may be a model configured to, using as supervised data an image of an eyeball and a direction actually viewed by the eyeball in the image, estimate the angle of the line of sight and the distance to an object in the line of sight based on an image of an eyeball. An AI program may be included in the display apparatus 1614, or may be included in the imaging apparatus, or may be included in an external apparatus. In a case where the AI program is included in the external apparatus, the AI program is transmitted to the display apparatus 1614 through communication.

In a case where display control is performed based on line-of-sight detection, the display control can be suitably applied to smart glasses further including an imaging apparatus that captures outside. The smart glasses can display information regarding the captured outside in real time.

As described above, the organic light-emitting apparatus according to at least any one of the first to fifth embodiments is applied to the variety of apparatuses according to the present embodiment, whereby it is possible to miniaturize the apparatus or achieve a higher definition of the apparatus in the same size. It is also possible to provide an apparatus in which variation in manufacturing is reduced.

For example, the present disclosure includes the following configurations.

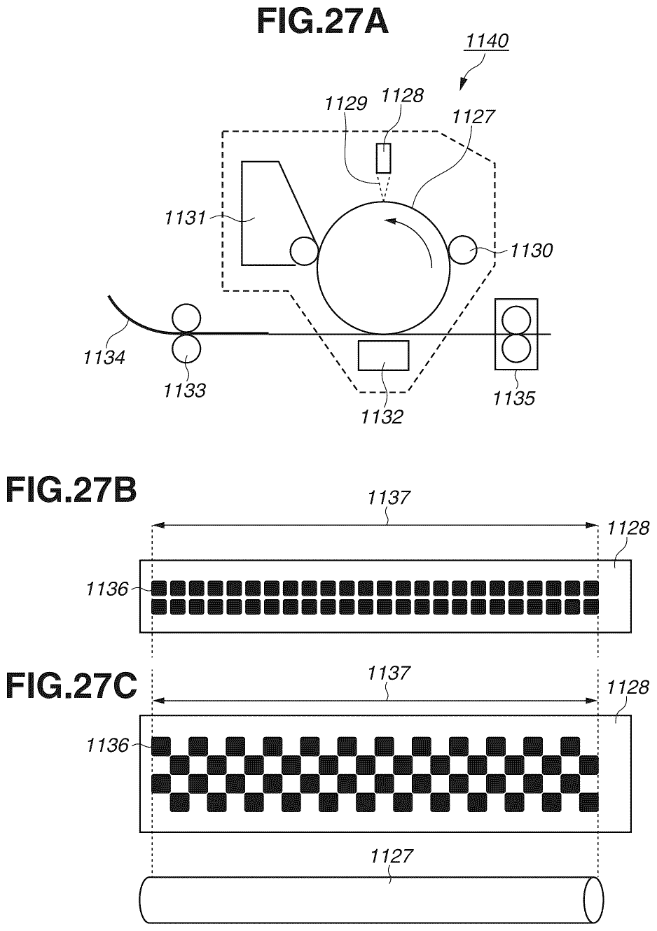

FIGS. 27A to 27C illustrate an image forming apparatus according to the present embodiment. FIG. 27A is a schematic view illustrating an image forming apparatus 1140 according to the present embodiment. The image forming apparatus 1140 includes a photosensitive member 1127, an exposure light source 1128, a development unit 1131, a charging unit 1130, a transfer device 1132, conveyance rollers 1133, and a fixing device 1135.

The exposure light source 1128 emits light 1129, and an electrostatic latent image is formed on the surface of the photosensitive member 1127. The exposure light source 1128 includes the light-emitting apparatus according to at least any one of the first to fifth embodiments. The development unit 1131 has toner or the like. The charging unit 1130 charges the photosensitive member 1127. The transfer device 1132 transfers a developed image to a recording medium 1134. The conveyance rollers 1133 convey the recording medium 1134. For example, the recording medium 1134 is paper. The fixing device 1135 fixes the image formed on the recording medium 1134.

FIGS. 27B and 27C are schematic views illustrating the state where a plurality of light-emitting units 1136 is placed on a long substrate in the exposure light source 1128. A direction 1137 indicates a direction parallel to the shaft of the photosensitive member 1127 and indicates the column direction in which organic light-emitting elements are arranged. This column direction is the same as the direction of an axis about which the photosensitive member 1127 rotates. This direction can also be referred to as “the long axis direction of the photosensitive member 1127”.

FIG. 27B illustrates a form in which light-emitting units 1136 are placed along the long axis direction of the photosensitive member 1127. FIG. 27C illustrates a form different from that in FIG. 27B, and is a form in which light-emitting units 1136 are alternately placed in the column direction in each of a first column and a second column. The first and second columns are placed at different positions in the row direction.

In the first column, a plurality of light-emitting units 1136 is placed at intervals. The second column has light-emitting units 1136 at positions corresponding to the intervals between the light-emitting units 1136 in the first column. That is, a plurality of light-emitting units 1136 is placed at intervals also in the row direction. As the light-emitting units 1136, the light-emitting apparatus according to at least any one of the first to fifth embodiments can be used.

The arrangement in FIG. 27C can be restated as, for example, the state where the light-emitting units 1136 are arranged in a grid pattern, the state where the light-emitting units 1136 are arranged in a houndstooth pattern, or a checkerboard pattern.

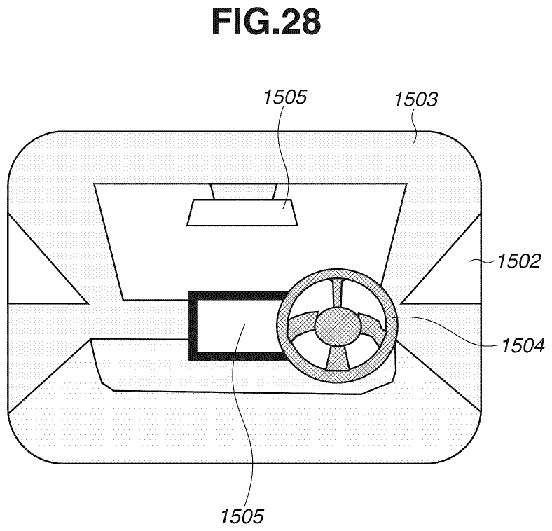

FIG. 28 is a schematic view of an automobile as an example of a movable body according to the present embodiment. An automobile 1500 includes a steering wheel 1504 that controls the moving direction of the movable body, a display unit 1505 that displays a map, the position of the movable body, the turn direction of the movable body, and the like and is mounted on a vehicle body 1503, and the like. The display unit 1505 may include the light-emitting apparatus according to at least any one of the first to fifth embodiments.

Although a description has been given using an automobile as an example, the movable body according to the present embodiment is not limited to an automobile. The movable body according to the present embodiment includes one or both of a driving force generation unit that generates a driving force mainly used to move the movable body, and a rotating body mainly used to move the movable body. The driving force generation unit can be an engine, a motor, or the like. The rotating body can be a tire, a wheel, a screw of a vessel, a propeller of a flying object, or the like. Specifically, the movable body may be a bicycle, an automobile, a train, a vessel, an aircraft, a drone, or the like.

The movable body may include a body and a lamp provided in the body or a display unit provided in the body. The lamp may emit light to notify a user of the position of the body. The lamp may include the light-emitting apparatus according to at least any one of the first to fifth embodiments. The display unit may include the light-emitting apparatus according to at least any one of the first to fifth embodiments.

In a case where a lens is used in a light-emitting apparatus, it is possible to reduce a decrease in luminance at a wide viewing angle.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Applications No. 2025-024828, filed Feb. 19, 2025, and No. 2025-187462, filed Nov. 6, 2025, all of which are hereby incorporated by reference herein in their entirety.

What is claimed is:

1. A light-emitting apparatus comprising:
a first light-emitting element disposed on a surface of a substrate in a first region;
a first lens disposed on the first light-emitting element and corresponding one-on-one to the first light-emitting element;
a second light-emitting element disposed on the surface of the substrate in a second region; and
a second lens disposed on the second light-emitting element and corresponding one-on-one to the second light-emitting element,
wherein the first and second regions are included in a display region,
wherein, in a first direction, a shortest distance from an end of the display region to the first region is greater than a shortest distance from the end of the display region to the second region,
wherein, in a planar view of the surface of the substrate, a distance in the first direction between a midpoint in the first direction of a light-emitting region of the second light-emitting element and a vertex of the second lens is longer than a distance in the first direction between a midpoint in the first direction of a light-emitting region of the first light-emitting element and a vertex of the first lens,
wherein a focal length of the second lens is longer than a focal length of the first lens, and
wherein a distance from a lower surface to the vertex of the second lens in a direction perpendicular to the surface of the substrate is smaller than a distance from a lower surface of the substrate to the vertex of the first lens in the perpendicular direction.

2. The light-emitting apparatus according to claim 1, wherein a radius of curvature of the second lens is larger than a radius of curvature of the first lens.

3. The light-emitting apparatus according to claim 1, further comprising:
a third light-emitting element disposed on the surface of the substrate in a third region disposed between the first and second regions in the first direction in the planar view; and
a third lens disposed on the third light-emitting element and corresponding one-on-one to the third light-emitting element,
wherein a focal length of the third lens is longer than the focal length of the first lens and is shorter than the focal length of the second lens.

4. The light-emitting apparatus according to claim 1, wherein, in the planar view, an area of the second region covers 5% to 90% of an area of the display region.

5. The light-emitting apparatus according to claim 1, further comprising:
a plurality of light-emitting elements including the first and second light-emitting elements; and
a plurality of lenses including the first and second lenses,
wherein, among the plurality of light-emitting elements and the plurality of lenses, in the planar view, as a position approaches from a center of the display region toward the end of the display region, a vertex of each of the lenses is shifted toward the end side in the first direction relative to a midpoint in the first direction of a light-emitting region of a light-emitting element corresponding to the lens.

6. The light-emitting apparatus according to claim 1, wherein, in a cross section passing through the first light-emitting element, the second light-emitting element, the first lens, and the second lens, a distance from the surface of the substrate to the lower surface of the first lens in a second direction perpendicular to the surface is smaller than a distance from the surface to the lower surface of the second lens in the second direction.

7. The light-emitting apparatus according to claim 1, further comprising:
a first color filter disposed on the first light-emitting element and corresponding to the first light-emitting element; and
a second color filter disposed on the second light-emitting element and corresponding to the second light-emitting element,
wherein, in the planar view, a distance in the first direction between the midpoint of the light-emitting region of the second light-emitting element and a midpoint in the first direction of the second color filter is greater than a distance in the first direction between the midpoint of the light-emitting region of the first light-emitting element and a midpoint in the first direction of the first color filter.

8. The light-emitting apparatus according to claim 1, further comprising an eyepiece optical system configured to guide light from the first and second lenses to an exit pupil.

9. The light-emitting apparatus according to claim 8, wherein the second region is located at a position at which a user cannot gaze through the eyepiece optical system.

10. The light-emitting apparatus according to claim 1, wherein, in the planar view, the light-emitting region of the second light-emitting element is larger than the light-emitting region of the first light-emitting element.

11. A display apparatus comprising:
the light-emitting apparatus according to claim 1; and
a transistor connected to an electrode included in the light-emitting apparatus.

12. A photoelectric conversion apparatus comprising:
an optical unit including a plurality of lenses;
an imaging element configured to receive light passing through the optical unit; and
a display unit configured to display an image captured by the imaging element,
wherein the display unit includes the light-emitting apparatus according to claim 1.

13. An electronic device comprising:
a display region of the light-emitting apparatus according to claim 1 as a display unit;
a housing in which the display unit is provided; and
a communication unit provided in the housing and configured to communicate with an external device.

14. Eyeglasses comprising:
a lens in which an imaging apparatus and a display unit are disposed; and
a control apparatus,
wherein the light-emitting apparatus according to claim 1 is disposed in the display unit, and
wherein the control apparatus controls operations of the imaging apparatus and the display unit.

15. A movable body comprising:
a vehicle body; and
a display unit mounted on the vehicle body,
wherein the display unit includes the light-emitting apparatus according to claim 1.

16. A light-emitting apparatus comprising:
a first light-emitting element disposed on a surface of a substrate in a first region;
a first lens disposed on the first light-emitting element and corresponding one-on-one to the first light-emitting element; and
a second light-emitting element disposed on the surface of the substrate in a second region,
wherein the first and second regions are included in a display region,
wherein, in a planar view of the surface of the substrate, the first region is surrounded by the second region, and
wherein the light-emitting apparatus does not include a lens corresponding to the second light-emitting element.

17. The light-emitting apparatus according to claim 16, further comprising:
a first color filter disposed on the first light-emitting element and corresponding to the first light-emitting element; and
a second color filter disposed on the second light-emitting element and corresponding to the second light-emitting element,
wherein, in the planar view, a distance in a first direction between a midpoint of a light-emitting region of the second light-emitting element and a midpoint in the first direction of the second color filter is greater than a distance in the first direction between a midpoint of a light-emitting region of the first light-emitting element and a midpoint in the first direction of the first color filter.

18. The light-emitting apparatus according to claim 16, further comprising:
a third light-emitting element disposed on the surface of the substrate in a third region disposed between the first and second regions in the planar view; and
a third lens disposed on the third light-emitting element and corresponding one-on-one to the third light-emitting element,
wherein a focal length of the third lens is longer than a focal length of the first lens.

19. The light-emitting apparatus according to claim 16, wherein, in the planar view, an area of the second region covers 5% to 90% of an area of the display region.

20. The light-emitting apparatus according to claim 16, further comprising:
a plurality of light-emitting elements including the first and second light-emitting elements; and
a plurality of lenses including the first lens,
wherein, among the plurality of light-emitting elements and the plurality of lenses, in the planar view, as a position approaches from a center of the display region toward the end of the display region, a vertex of each of the plurality of lenses is shifted to an end side in the first direction relative to a midpoint in the first direction of a light-emitting region of one of the plurality of light-emitting elements corresponding to each of the plurality of lenses.

21. The light-emitting apparatus according to claim 16, further comprising an eyepiece optical system configured to guide light from the first lens to an exit pupil.

22. The light-emitting apparatus according to claim 21, wherein the second region is located at a position at which a user cannot gaze through the eyepiece optical system.

23. The light-emitting apparatus according to claim 16, wherein, in the planar view, a light-emitting region of the second light-emitting element is larger than a light-emitting region of the first light-emitting element.

24. A display apparatus comprising:
the light-emitting apparatus according to claim 16; and
a transistor connected to an electrode included in the light-emitting apparatus.

25. A photoelectric conversion apparatus comprising:
an optical unit including a plurality of lenses;
an imaging element configured to receive light passing through the optical unit; and
a display unit configured to display an image captured by the imaging element,
wherein the display unit includes the light-emitting apparatus according to claim 16.

26. An electronic device comprising:
a display region of the light-emitting apparatus according to claim 16 as a display unit;
a housing in which the display unit is provided; and
a communication unit provided in the housing and configured to communicate with an external device.

27. Eyeglasses comprising:
a lens in which an imaging apparatus and a display unit are disposed; and
a control apparatus,
wherein the light-emitting apparatus according to claim 16 is disposed in the display unit, and
wherein the control apparatus controls operations of the imaging apparatus and the display unit.

28. A movable body comprising:
a vehicle body; and
a display unit mounted on the vehicle body,
wherein the display unit includes the light-emitting apparatus according to claim 16.
